(19) United States
(12) Patent Application Publication
(10) Pub. No.: US 2024/0055472 A1
(43) Pub. Date: Feb. 15, 2024

(54) ELECTRONIC SEMICONDUCTOR COMPONENT, AND METHOD FOR MANUFACTURING A PRETREATED COMPOSITE SUBSTRATE FOR AN ELECTRONIC SEMICONDUCTOR COMPONENT

(71) Applicant: MI2-FACTORY GMBH, Jena (DE)

(72) Inventors: Constantin CSATO, Stammbach (DE); Florian KRIPPENDORF, Jena (DE)

(21) Appl. No.: 18/267,872

(22) PCT Filed: Dec. 10, 2021
(86) PCT No.: PCT/EP2021/085296

§ 371 Date: Jun. 16, 2023

(30) Foreign Application Priority Data
Dec. 18, 2020 (DE) 10 2020 134 222.5
Apr. 16, 2021 (DE) 10 2021 109 690.1

(51) Int. Cl. H01L 29/04; H01L 29/16; H01L 21/04

(52) U.S. Cl. CPC H01L 29/045; H01L 29/1608; H01L 21/0465

(57) ABSTRACT

A electronic semiconductor component includes a crystal made of monocrystalline SiC, wherein the orientation of at least some subareas of a first surface of the SiC crystal extends substantially in a direction running perpendicularly to the c direction of the crystal structure of the crystal. Also disclosed is a manufacturing process.

### BACKGROUND OF THE INVENTION

The invention relates to an electronic semiconductor component and to a method for manufacturing a pretreated composite substrate for an electronic semiconductor component.

Discrete highly blocking power semiconductor components with a nominal blocking voltage of more than 600 V are generally constructed vertically both in silicon and in SiC. What this means for diodes, e.g. MPS (merged pin Schottky) diodes, Schottky diodes or p-n diodes, is that the cathode is disposed on the front side of the substrate and the anode on the reverse side of the substrate. A similar arrangement is applicable in the case of vertical power MOS (metal oxide semiconductor) components. Gate electrodes and source electrodes are on the front side of the substrate, the drain electrode on the reverse side of the substrate. The actual transistor element or the channel region in conventional power MOSFETs may be arranged parallel to the surface (D-MOS) or perpendicularly to the surface (trench MOS). Specific constructions have become established for SiC MOSFETs, e.g. trench transistors.

The width of the drift zone (=active zone, voltage-absorbing layer) is adjusted depending on the reverse blocking voltage required. For example, the width of the drift zone for a 600 V MOSFET component in silicon will be about 50 μm.

In the case of what are called superjunction components, the width of the voltage-absorbing layer may be somewhat reduced compared to “simple” vertical MOSFETs. The particular feature of this type of vertical components is that the drift zone is characterized by an alternating arrangement of vertical p- and n-doped columns. The additionally introduced p doping in the case of blocking compensates for the elevated charge in the n-doped region, which, in the on state, determines the resistance between the source electrode and drain electrode. Thus, with the same blocking capacity, the on-resistance may be reduced roughly by up to a factor of 10 compared to conventional vertical MOS transistors. The actual transistor element, or the channel region in superjunction MOSFET architectures, may be arranged parallel to the surface (D-MOS) or perpendicularly to the surface (trench MOS).

The specific material properties of SiC, for vertical power semiconductor components, require the provision of specific production methods and the use of specific architectures of the channel and transistor regions.

Usually, the active zones of all vertical power diodes or all power transistors (MOSFET and J-FET) are formed in monocrystalline epitaxial layers. These epitaxial layers are formed or deposited on crystalline carrier wafers. This means that the doping and vertical extent (thickness) of the active epitaxial zone can be matched to the respective blocking voltage, and the highly doped carrier wafer can be optimized in terms of its doping so as to minimize its contribution to the on-resistance.

Especially in the case of SiC substrates, the above-described production of the layer structure is complex and costly, since the epitaxial layer deposition and also the provision of monocrystalline carrier wafers is enormously costly. Moreover, in this manner of production, the wafer surface is arranged at an angle of 4° to a direction perpendicularly to the c direction of the crystal structure. This firstly increases complexity and secondly reduces the performance of many structural elements of the semiconductor components that are to be introduced into the wafer, especially of the channel regions, Schottky junctions or switching p-n junctions.

For example, charge carrier mobility is reduced in the case of the 4° tilt. In the case of trench MOSFETs, this leads, for instance, to the necessity of implementing non-perpendicular trenches (deviation of 4°) in order to compensate for or optimize the reduction in charge carrier mobility in the MOS channel. In the case of planar MOS transistors where the channel region runs parallel to the surface of the wafer, the deviation of 4° in the channel region from the optimal plane (0001), including the associated reduction in charge carrier mobility for lack of implementable technological measures of remedy, is typically accepted.

DE 10 2019 112 985 A1 proposes, as an alternative, producing the semiconductor component without epitaxial deposition by splitting a substrate from an SiC wafer, followed by ion implantation in the drift zone using an energy filter.

### SUMMARY OF THE INVENTION

It is an object of the present invention to provide an electronic semiconductor component which has high performance and high quality. It should also be manufactured industrially with reduced complexity and lower costs. A corresponding method of manufacturing a pretreated composite substrate for the electronic semiconductor component is likewise provided.

According to an aspect of the invention, the electronic semiconductor component, which is preferably a vertical semiconductor component and more preferably a highly blocking vertical semiconductor component, has a crystal made of monocrystalline SiC, wherein the orientation of at least subsections of a first surface of the crystal made of SiC deviates by less than 0.5°, preferably by less than 0.3°, more preferably by less than 0.1°, most preferably not at all, from a direction perpendicularly to the c direction of the crystal structure of the crystal.

In this way, the performance of the semiconductor component is optimized.

In general, the following nomenclature is applicable:
The C plane (carbon-terminated) of the crystal structure and the Si plane (silicon-terminated) of the crystal structure are arranged perpendicularly to the c direction of the crystal structure.
The (0001) plane and the (0001̅) plane of the crystal structure are arranged perpendicularly to the c direction of the crystal structure.

Each surface or plane which is specified as running in a direction perpendicularly to the c direction in the present document runs either in a C plane (carbon-terminated) of the crystal structure or in an Si plane (silicon-terminated) of the crystal structure. Each surface or plane which is specified as running in a direction perpendicularly to the c direction in the present document runs in a (0001) plane or in a (0001̅) plane of the crystal structure.

Correspondingly, each surface or plane which is specified as running in a direction parallel to the c direction in the present document runs perpendicularly to the C plane (carbon-terminated) of the crystal structure and perpendicularly to the Si plane (silicon-terminated) of the crystal structure. Likewise, each surface or plane which is specified as running in a direction parallel to the c direction in the present document runs perpendicularly to the (0001) plane and to the (0001̅) plane of the crystal structure.

Especially for the first surface of the crystal, at least subsections thereof may be arranged either in a C plane (carbon-terminated) of the crystal structure (0001̅) or in an Si plane (silicon terminated) of the crystal structure (0001).

The second surface of the crystal, which is generally continuous, opposite the first surface of the crystal of SiC likewise deviates by less than 0.5°, preferably by less than 0.3°, more preferably by less than 0.1°, most preferably not at all, from a direction perpendicularly to the c direction of the crystal structure of the crystal.

In a particularly preferred configuration, the electronic semiconductor component has an active component region comprising:
a first zone having a near-surface shielding structure or JFET structure in a region comprising at least subsections of the first surface of the crystal;
a second zone having a voltage-absorbing layer, disposed on the side of the first zone remote from the first surface of the crystal and adjoining the first zone; and
a field-free contact zone or field stop zone disposed on the side of the voltage-absorbing layer remote from the first zone.

At least subregions of the second zone are preferably doped, preferably the entire second zone. These subregions or the entire second zone are preferably p- or n-doped with a dopant concentration of 1E15 cm⁻³ to 5E17 cm⁻³.

It is preferable when the second zone is doped with one of the following elements: nitrogen, phosphorus, boron or aluminum.

At least subregions of the first zone are preferably doped.

It is preferable when at least these subregions of the first zone are doped with one of the following elements: nitrogen (N), phosphorus (P), boron (B) or aluminum (Al). Preferably, the first zone and the second zone are doped with the same type of ion.

It is preferable that the first zone and the second zone are formed substantially on the basis of the crystal made of SiC.

The thickness of the first zone is preferably between 0.5 μm and 3.0 μm.

The thickness of the second zone is preferably between 2 μm and 50 μm, more preferably between 3 μm and 25 μm, especially preferably between 3 μm and 15 μm.

A dopant concentration in an n-doped region of the first zone is preferably higher than a dopant concentration in an n-doped region of the second zone that faces the first zone, preferably higher by a factor of 1.5 to 100, more preferably by a factor of 2 to 10.

A dopant concentration in a p-doped region of the first zone is preferably higher than a dopant concentration in an n-doped region of the second zone that faces the first zone, preferably higher by a factor of 2 to 1000, more preferably by a factor of 50 to 1000.

In one configuration, the second zone, proceeding from the first zone, has a substantially constant dopant depth profile in the direction towards the field-free contact zone or field stop zone.

Alternatively, the second zone, proceeding from the first zone, in the direction towards the field free contact zone or field stop zone, can have a dopant depth profile that rises in steps, wherein the steps are formed in a region of the second zone facing the field-free contact zone or field stop zone by up to 40%, preferably up to 30%, of the total depth of the second zone.

In this case, a difference in concentration between the highest and lowest steps is preferably at least a factor of 10, preferentially at least a factor of 100, more preferably at least a factor of 500, especially preferably at least a factor of 1000.

In the stepped doping profile, it is preferable that the depthwise extent of the flank regions of the steps predominates over the depthwise extent of the stepped plateau.

In a further preferred alternative configuration, the second zone, proceeding from the first zone, has a constantly rising dopant depth profile in the direction towards the field-free contact zone or field stop zone.

The continuously rising dopant depth profile of the second zone is preferably a profile according to the following formula:

$$D ( z ) = {D}_{max} \cdot ( \frac{1}{\sqrt{1 + ∝ ( 1 - \frac{z}{b} )}} \cdot f ) + {D}_{0}$$

wherein
Dₘₐₓ is the maximum dopant concentration,
α is a value between 10 and 10 000,
z is the distance from the first zone,
b is the thickness of the second zone,
f is a tolerance factor between 0.95 and 1.05,
D₀ is the background doping,
   wherein

$${D}_{max} \geq \frac{{ε}_{r} {ε}_{0} {E}_{max}}{2 {e}_{0} {V}_{b r}}$$

wherein
Eₘₐₓ is the maximum field,
εᵣ is the relative dielectric constant of the semiconductor,
ε₀ is the dielectric constant in a vacuum,
e₀ is the elementary charge of the electron,
V_{br} is the breakthrough voltage,
   and wherein

$$b \geq \frac{3 {V}_{b r}}{2 {E}_{max}}$$

The stepped profile mentioned, or the continuously rising profile, takes two aspects into account. Firstly, this dopant profile achieves an optimal compromise between the on-resistance and the given voltage stability. Secondly, the dopant profile has such a high concentration toward the field-free contact zone or field stop zone that field punch-through is virtually ruled out.

In one embodiment, there is an overlap region of the respective dopant depth profiles in a junction section between the first zone and the second zone. The two dopant depth profiles preferably have overlapping obliquely declining flanks. The combination of the two dopant depth profiles of the first and the second zone may be a constant profile, a profile that rises in steps toward the field-free contact zone or field stop zone, or a profile that rises continuously toward the field-free contact zone or field stop zone.

Particular preference is given to a profile in which there is a stepped decline in the dopant profile from the first zone to the second zone, and then, within the second zone, a constant profile, a profile that rises in steps toward the field-free contact zone or field stop zone, or a profile that rises continuously toward the field-free contact zone or field stop zone.

It is preferable that the electronic semiconductor component has a (field-free) carrier substrate on the side of the field-free contact zone or field stop zone remote from the first zone, wherein the crystal made of SiC is bonded to the carrier substrate by means of a permanent adhesive bond or bonded connection in the region of the field-free contact zone or field stop zone.

It is preferable that the carrier substrate is thermally stable up to at least 1500° C. and has a coefficient of linear expansion that deviates by not more than 20%, preferably by not more than 10%, from the coefficient of linear expansion of SiC.

In a particularly preferred configuration, the carrier substrate is formed from polycrystalline SiC or graphite.

Alternatively, the electronic semiconductor component may also be a self-supporting thin layer based on the crystal of SiC without carrier substrate.

In a preferred configuration, the electronic semiconductor component has been provided with an inactive edge region that substantially completely surrounds the first and second zones laterally in all directions.

In one configuration, the edge region is substantially undoped, apart from any near-surface field-reducing edge structure present.

In an alternative configuration, the edge region, apart from any near-surface field-reducing edge structure present, is substantially undoped from the first surface onward and, substantially from a depth at which the second zone commences up to a depth at which the field-free contact zone or field stop zone lies, has been provided with the same dopant concentration as the second zone or has been provided with a lower dopant concentration than the second zone, preferably with a lower dopant concentration by at least 20%, more preferably with a lower dopant concentration by at least 50%.

Preferably, the field-free contact zone or field stop zone has a vertical thickness of not more than 2 μm, preferably not more than 1 μm.

Preferably, the monocrystalline SiC is of the hexagonal 4H or 6H polytype.

Preferably, the crystal is a crystal made of high-quality semi-insulating SiC material of high purity. Preference is given here to an HT-CVD (high temperature chemical vapor deposition) material.

In a preferred configuration, the A plane of the crystal (112̅0) deviates by less than 0.5°, more preferably by less than 0.3°, even more preferably by less than 0.1°, most preferably not at all, from a direction perpendicularly to the first surface of the crystal.

In a preferred configuration, the electronic semiconductor component is a trench MOSFET, and the channel region deviates by less than 0.5°, more preferably by less than 0.3°, even more preferably by less than 0.1°, most preferably not at all, from the c direction of the crystal structure of the crystal.

Alternatively or additionally, in the case of configuration as a trench MOSFET, it is preferable that the channel region is arranged substantially perpendicularly to the first surface of the crystal.

In the latter case, it is also preferable that the channel region is arranged in an A plane of the crystal.

In an alternative preferred configuration, the electronic semiconductor component is a planar MOSFET, and the channel region deviates by less than 0.5°, more preferably by less than 0.3°, even more preferably by less than 0.1°, most preferably not at all, from a direction perpendicularly to the c direction of the crystal structure of the crystal.

Alternatively or additionally, in the case of configuration as a planar MOSFET, it is preferable that the channel region runs parallel to the first surface of the crystal.

In a further alternative preferred configuration, the electronic semiconductor component is an MPS (merged PIN Schottky) diode, and the plane parallel to the Schottky junction deviates by less than 0.5°, more preferably by less than 0.3°, even more preferably by less than 0.1°, most preferably not at all, from a direction perpendicularly to the c direction of the crystal structure of the crystal.

Alternatively or additionally, in the case of configuration as an MPS diode, it is preferable that the plane of the Schottky junction is arranged parallel to the first surface of the crystal.

In a further alternative preferred configuration, the electronic semiconductor component is a JFET transistor (junction field effect transistor), wherein the interface at one or each p⁺-n junction deviates by less than 0.5°, preferably by less than 0.3°, more preferably by less than 0.1°, most preferably not at all, from a direction parallel to the c direction of the crystal structure of the crystal.

In a further alternative preferred configuration, the electronic semiconductor component is a JFET transistor, wherein the interface at one or each p⁺-n junction deviates by less than 0.5°, preferably by less than 0.3°, more preferably by less than 0.1°, most preferably not at all, from a direction perpendicularly to the c direction of the crystal structure of the crystal.

According to another aspect of the invention, the method of manufacturing a pretreated composite substrate, which serves as a basis for further processing into an electronic semiconductor component and has an acceptor substrate and a first section of a donor substrate that has at least one doped layer, comprises the steps of:
a) providing the donor substrate including monocrystalline SiC;
b) doping a first layer in the donor substrate by ion implantation using an energy filter, wherein the energy filter is a microstructured membrane having a predefined structure profile for adapting a dopant depth profile caused by the implantation in the first layer in the donor substrate, wherein the doping creates a predetermined dopant depth profile in the first layer of the donor substrate, wherein the first layer extends from an outer face of the donor substrate which faces the ion beam up to a predetermined dopant depth, followed by a remaining portion of the donor substrate;
c) creating an intended breakage site in the donor substrate that runs substantially parallel to the outer face of the donor substrate;
d) providing the acceptor substrate and producing a bond between donor substrate and acceptor substrate, wherein the first layer is arranged in a region between the acceptor substrate and the remaining portion of the donor substrate;
e) splitting the donor substrate in the region of the intended breakage site for creation of the pretreated composite substrate, wherein the pretreated composite substrate includes the acceptor substrate and the first section of the donor substrate which is connected thereto and has at least one doped layer, wherein the doped layer comprises at least a section of the first layer of the donor substrate, wherein the splitting is effected in such a way that the first section of the donor substrate, in the composite substrate, in the region of the intended breakage site, has a first surface facing away from the acceptor substrate that deviates by less than 0.5°, preferably by less than 0.3°, more preferably by less than 0.1°, most preferably not at all, from a direction perpendicularly to the c direction of the crystal structure of the first section of the donor substrate.

The first layer always consists of monocrystalline SiC. The donor substrate preferably consists entirely of monocrystalline SiC.

The first layer preferably has a thickness of 3 to 15 μm. Ion implantation can viably be conducted over a thickness of this order of magnitude.

In a preferred embodiment, the donor substrate is a crystal made of high-quality monocrystalline semi-insulating SiC material of high purity. In particular, this is understood to mean a material wherein the concentration of elemental impurities, especially N, B, P, is predominantly less than 5E15 cm⁻³. What is meant by “predominantly” in this connection is that the criterion is applicable virtually throughout the depth profile, but there may be deviations in particular regions, for example at the surface. Preference is given here to HT-CVD (high temperature chemical vapor deposition) material.

In a preferred embodiment, the donor substrate is composed of SiC of the 4H, 6H or 3C polytype. These polytypes have been found to be advantageous for the production of semiconductor components.

Preferably, the outer face of the donor substrate facing the ion beam deviates by less than 0.5°, more preferably by less than 0.3°, even more preferably by less than 0.1°, most preferably not at all, from a direction perpendicularly to the c direction of the crystal structure of the donor substrate. The particular benefit in the case of virtually 0° is that the donor substrate can be severed parallel to the outer face and hence more individual wafers can be obtained from one cylinder.

The donor substrate preferably has a thickness of more than 100 μm, preferably more than 200 μm, more preferably more than 300 μm, up to 15 cm, more preferably up to 10 cm.

It is generally preferable that the doping of the first layer affords p or n doping with a dopant concentration or defect concentration in the first layer of 1E15 cm⁻³ to 5E17 cm⁻³. This dopant concentration or defect concentration is of very good suitability for the drift zone (active layer, power-absorbing layer) of a multitude of high-performance components. The doping may be constant across the thickness of the first layer or may show a different doping profile.

The first layer is preferably doped with ions of one of the following elements: nitrogen, phosphorus, boron or aluminum.

The primary energy range of the ion beam in the doping of the first layer is preferably between 1 MeV and 50 MeV.

In a preferred embodiment, the doping of the first layer gives a constant dopant depth profile or a substantially constant dopant depth profile. This is understood to mean profiles with a deviation from a perfectly flat dopant depth profile of less than 20% and preferably less than 10%. In reality, the plateau is adjoined by a declining flank, i.e. the decline in the profile is not vertical or abrupt in the region of the doping depth.

In an alternative configuration, the doping of the first layer affords a dopant depth profile that declines in steps from an outer face of the donor substrate that faces the ion beam, wherein the steps are formed in a near-surface region of the first layer that faces the ion beam by up to 40%, preferably up to 30%, of the total depth of the first layer.

A difference in concentration here between the highest and lowest steps is preferably at least a factor of 10, preferably at least a factor of 100, more preferably at least a factor of 500, especially preferably at least a factor of 1000.

The depthwise extent of the flank regions of the steps is predominant here over the depthwise extent of the stepped plateau.

In an alternative configuration, the doping of the first layer affords a dopant depth profile continuously declining from an outer face of the donor substrate that faces the ion beam.

It is preferable here when the continuously declining dopant depth profile is a profile according to the following formula:

$$D ( z ) = {D}_{max} \cdot ( 1 - \frac{1}{\sqrt{1 + ∝ ( 1 - \frac{z}{b} )}} \cdot f ) + {D}_{0}$$

wherein
Dₘₐₓ is the maximum dopant concentration,
α is a value between 10 and 10 000,
z is the distance from the outer face,
b is the thickness of the first layer,
f is a tolerance factor between 0.95 and 1.05,
D₀ is the background doping,
   wherein

$${D}_{max} \geq \frac{{ε}_{r} {ε}_{0} {E}_{max}}{2 {e}_{0} {V}_{b r}}$$

wherein
Eₘₐₓ is the maximum field,
εᵣ is the relative dielectric constant of the semiconductor,
C₀ is the dielectric constant in a vacuum,
e₀ is the elementary charge of the electron,
V_{br} is the breakthrough voltage,
   and wherein

$$b \geq \frac{3 {V}_{b r}}{2 {E}_{max}}$$

In general, preference is given to the further step of creating a contact layer in a surface region of the first layer, or of applying a contact layer to the outer face of the first layer, wherein the bond between the donor substrate and acceptor substrate is established via the contact layer, resulting in the following sequence: acceptor substrate, contact layer, remaining portion of first layer or first layer, remaining portion of the donor substrate. This can achieve a particularly good, low resistance connection between donor substrate and acceptor substrate.

The contact layer is preferably created by ion implantation.

A dopant concentration in the contact layer is preferably at least 100 times, preferably at least 1000 times, more preferably at least 10 000 times, even more preferably at least 100 000 times, greater than an average dopant concentration in the remainder of the first layer or in the first layer. This achieves a very low-resistance bond, and punch-through of the field to the interface in the semiconductor component is prevented.

In a preferred configuration, a dopant concentration in the contact layer is more than 1E17 cm⁻³, more preferably more than 1E19 cm⁻³.

The intended breakage site is preferably in the region of the first layer, more preferably in an end region of the first layer close to the predetermined doping depth, wherein the end region is more preferably not thicker than 1 μm. In this way, a minimum amount of doped material remains on the donor substrate after the splitting.

In an alternative configuration, the intended breakage site is in the region of the remaining portion of the donor substrate, and, in addition, after step e), the further step of performing ion implantation into the composite substrate is performed from the side remote from the acceptor substrate. This has the advantage that an active zone with a greater total thickness can be formed. On account of the overlap thus enabled between two different implantations, it is also possible to create different preferred dopant profiles, or to create preferred dopant profiles stepwise.

In the context of this alternative configuration, it is preferable that the ion implantation into the composite substrate provides a dopant depth profile in a supplementary doped layer that extends at least up to the doped layer.

The ion implantation into the composite substrate is performed, for example, in such a way that the combination of the two dopant depth profiles of the doped layer and of the supplementary doped layer is a constant profile, a profile that rises stepwise toward the acceptor substrate, or a profile that rises continuously toward the acceptor substrate. Other profile forms are also conceivable.

Obliquely declining flanks in the transition region of the two dopant depth profiles of the doped layer and of the supplementary doped layer may overlap one another.

Particular preference is given to a configuration in which the dopant concentration in the supplementary doped layer is higher than in a region of the doped layer that faces the supplementary doped layer, preferably higher by a factor of 1.5 to 100, more preferably by a factor of 2 to 10. The dopant concentration in the doped layer may again be a constant profile, a profile that rises stepwise toward the acceptor substrate, or a profile that rises continuously toward the acceptor substrate.

Preference is given to creating the intended breakage site by ion implantation of split-triggering ions.

The split-triggering ions are preferably introduced over the entire width of the donor substrate in order to create a very uniform separation surface.

Alternatively, the split-triggering ions may be introduced only over a portion of the width of the donor substrate. This reduces complexity in the ion implantation.

Preference is given to introducing the split-triggering ions only in an edge region of the donor substrate.

In preferred embodiments, the split-triggering ions are selected from the following: hydrogen (H or H₂), helium (He), boron (B).

In principle, it is advantageous when the split-triggering ions are high-energy ions having an energy between 0.5 and 10 MeV, preferably between 0.5 and 5 MeV, more preferably between 0.5 and 2 MeV.

A particle dose of the split-triggering ions is preferably in each case between 1E15 cm⁻² and 5E17 cm⁻². This dose achieves reliable splitting.

The energy spread (ΔE/E) of the ion beam of the split-triggering ions is preferably less than 10⁻², more preferably less than 10⁻⁴. In this way, it is ensured that the intended breakage site has minimum thickness, and the energy loss peak of the ions at the intended breakage site is very sharp.

The splitting of the donor substrate is preferably triggered by a thermal treatment of the donor substrate at a temperature between 600° C. and 1300° C., preferably between 750° C. and 1200° C., more preferably between 850° C. and 1050° C. Alternatively, mechanical methods are also conceivable.

In a preferred embodiment, the bond is established by a thermal treatment of the composite substrate at a temperature between 800° C. and 1600° C., preferably between 900° C. and 1300° C.

It is conceivable that the method is simplified in that both the establishment of the bond and the splitting of the donor substrate are effected by a thermal treatment, with both steps being conducted simultaneously.

Preferably, the step of bonding is preceded by a pretreatment of at least one, preferably both, of the surfaces to be bonded, especially a wet-chemical treatment, plasma treatment or ion beam treatment.

The acceptor substrate is preferably thermally stable up to at least 1500° C. and has a coefficient of linear expansion that deviates by not more than 20%, preferably by not more than 10%, from the coefficient of linear expansion of SiC. This effectively prevents bending of the composite substrate.

In a particularly preferred configuration, the acceptor substrate is formed from polycrystalline SiC or graphite.

Preferably, the splitting step is followed by an aftertreatment of the surface of the composite substrate in the region of the intended breakage side, especially by polishing and/or removing (near-surface) defects.

In a preferred extension of the method, implantation defects in the pretreated composite substrate are annealed at temperatures between 1500° C. and 1750° C. This can be accomplished during the production of the pretreated composite substrate or else only later in the further processing into an electrical semiconductor component.

In a preferred extension of the method, the pretreated composite substrate is used to produce an electronic semiconductor component which is preferably a vertical semiconductor component and more preferably a highly blocking vertical power semiconductor component, in that further structural elements of the semiconductor component are introduced into the composite substrate from the first surface or on the first surface or disposed on the first surface.

Examples of structural elements are: active and passive areas of different doping (source, J-FET p-doped gate structure; MOSFET channel, shielding areas, p-n junctions, resurf edge areas, source-gate contact areas, J-FET channel area), insulation oxides, gate oxides, contact areas (metals, silicides), Schottky electrodes (metals, alloys), ohmic electrodes, source-gate metallization or wires, passivation layers, trenches for gate electrodes, bonding pads, contact holes or contact trenches.

In the context of this description, a first and second zone have been described for the semiconductor component, while a doped layer and a supplementary doped layer have been described for the pretreated composite substrate. The first zone may have been formed together with the second zone solely from the doped layer of the composite substrate if there is no additional doped layer. It is likewise possible to form the first zone from the supplementary doped layer, while the second zone is formed from the doped layer. Finally, it is also possible that a doped layer and a supplementary doped layer are present in the composite substrate, but the boundary between the first and second zones in the semiconductor component is not at the junction between the doped layer and supplementary doped layer, but rather within the doped layer or within the supplementary doped layer.

### BRIEF DESCRIPTION OF THE DRAWINGS

FIG. 1 is a schematic cross-sectional view of a first configuration of the donor substrate that can be used in the method according to an aspect of the invention.

FIG. 2 is a schematic view of an irradiation arrangement with an energy filter for irradiation of the donor substrate.

FIG. 3 is a schematic diagram of the mode of action of an energy filter that can be used in the method according to an aspect of the invention.

FIG. 4 is a schematic diagram of different doping profiles that can be produced by means of differently structured energy filters.

FIG. 5 shows a schematic of the doping profile of the first layer of the donor substrate and a resultant doping profile of the donor substrate.

FIG. 6 shows various options for the doping profile of the first layer of the donor substrate.

FIG. 7 shows a schematic of the creation or application of a contact layer in the donor substrate.

FIG. 8 shows a schematic of a first variant of the creation of an intended breakage site in the donor substrate.

FIG. 9 shows a schematic of a second variant of the creation of an intended breakage site in the donor substrate.

FIG. 10 shows a schematic of the producing of a bond between donor substrate and acceptor substrate.

FIG. 11 shows a schematic of the splitting of the remaining portion of the donor substrate from the composite substrate.

FIG. 12 shows a schematic of the aftertreating of the surface of the composite substrate in the region of the split site.

FIG. 13 shows a schematic of a cross section through an embodiment of the pretreated composite substrate according to an aspect the invention.

FIG. 14 shows a schematic of a cross section through a further embodiment of the pretreated composite substrate according to an aspect the invention and the corresponding dopant profile.

FIG. 15 is a schematic diagram of the splitting of a wafer bar that functions as donor substrate when used for the multiple creation of a composite substrate from a donor substrate.

FIG. 16 shows a schematic of the doping profile of the first layer of the donor substrate using partial masking of the donor substrate, and a resultant alternative doping profile of the donor substrate.

FIG. 17 shows a schematic of the cross section of an illustrative base structure of a semiconductor component according to an aspect of the invention.

FIG. 18 shows a schematic of the cross section of an alternative illustrative base structure of a semiconductor component according to an aspect of the invention.

FIG. 19 shows a schematic of the cross section of an embodiment of the semiconductor component according to an aspect of the invention in the form of a planar MOS transistor.

FIG. 20 shows a schematic of preferred dopant profiles for particular embodiments of the semiconductor component according to an aspect of the invention.

FIG. 21 shows a schematic of the cross section of an embodiment of the semiconductor component according to an aspect of the invention in the form of a vertical merged PIN Schottky diode.

FIG. 22 shows a schematic of the cross section of an embodiment of the semiconductor component according to an aspect of the invention in the form of another configuration of a vertical merged PIN Schottky diode.

FIG. 23 shows a schematic of the cross section of an embodiment of the semiconductor component according to an aspect of the invention in the form of a vertical trench MOSFET.

FIG. 24 shows a schematic of the cross section of an embodiment of the semiconductor component according to an aspect of the invention in the form of another configuration of a vertical trench MOSFET.

FIG. 25 shows a schematic of the cross section of an embodiment of the semiconductor component according to an aspect of the invention in the form of a vertical superjunction MOSFET.

FIG. 26 shows a schematic of a top view of the superjunction MOSFET from FIG. 25.

FIG. 27 shows a schematic of the cross section of an embodiment of the semiconductor component according to an aspect of the invention in the form of a J-FET.

FIG. 28 shows a schematic of the cross section of an embodiment of the semiconductor component according to an aspect of the invention in the form of another configuration of a J-FET.

### DETAILED DESCRIPTION OF SPECIFIC EMBODIMENTS

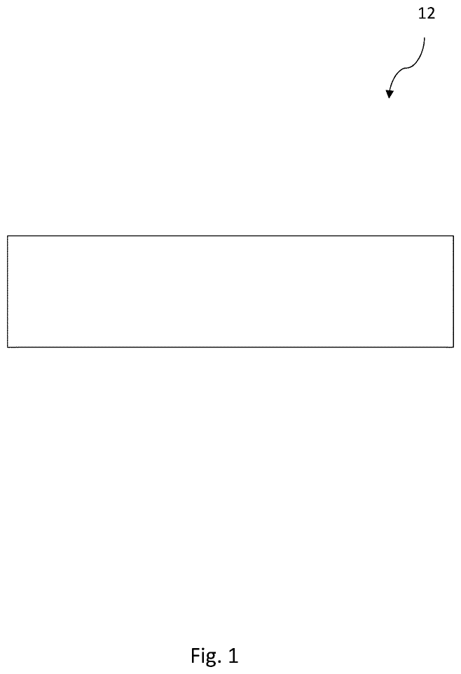

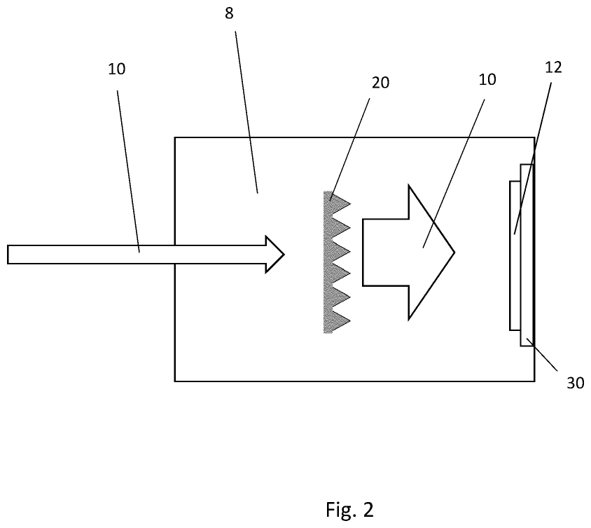

The method according to an aspect of the invention for manufacturing a pretreated composite substrate commences with the provision of a donor substrate 12 including or consisting entirely of monocrystalline silicon carbide (SiC); see FIGS. 1 and 2.

The embodiment of the donor substrate 12 shown in FIG. 1 is a wafer composed of high-quality semi-insulating SiC material of high purity. In particular, this is understood to mean a material wherein the concentration of elemental impurities, for example N, B, P, is less than 5E15 cm⁻³. What is meant by “predominantly” in this connection is that the criterion is applicable virtually throughout the depth profile, but there may be deviations in particular regions, for example at the surface. Particular preference is given to HT-CVD (high temperature chemical vapor deposition) material.

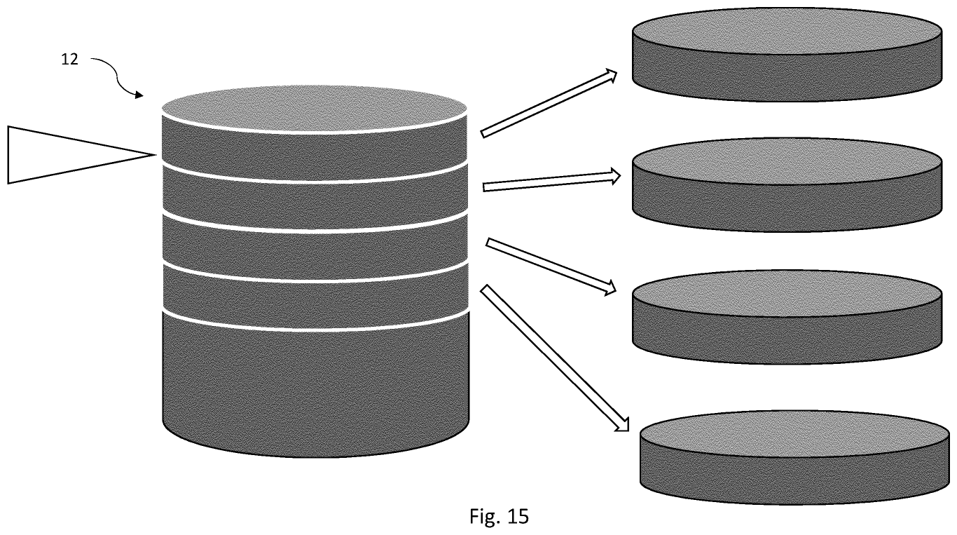

The donor substrate 12 according to FIG. 1 preferably has a thickness of more than 100 μm, preferably more than 200 μm, more preferably more than 300 μm, up to 15 cm, preferably up to 10 cm. It may especially take the form of an undoped or weekly n-doped wafer bar; see FIG. 15.

In a preferred embodiment, the donor substrate is composed of SiC of the 4H, 6H or 3C polytype. These polytypes have been found to be advantageous for the characteristics of the semiconductor components to be produced therewith.

In the embodiment shown, the outer face of the donor substrate 12 has a deviation of 0° from a perpendicular to the c direction. The outer face thus runs in a (0001) plane or in a plane (0001̅) of the crystal structure.

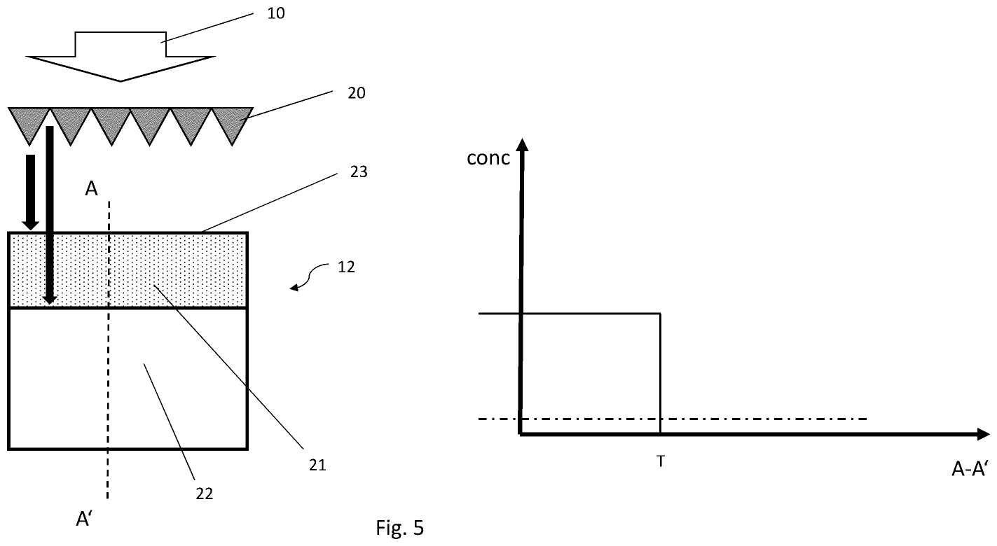

After the donor substrate 12 has been provided, a first layer 21 in the donor substrate is doped (see FIG. 5), which, in the finished component, later assumes or partly assumes at least the function of the drift zone (also called active zone or voltage-absorbing zone). This doping of the first layer 21 in the donor substrate 12 is effected by ion implantation using an energy filter 20. The corresponding fundamental construction is shown in FIG. 2.

FIG. 2 shows an irradiation chamber 8 in which there is typically a high vacuum. The irradiation chamber 8 accommodates the donor substrate 12 to be doped in a substrate holder 30.

An ion beam 10 is generated by means of a particle accelerator (not shown) and guided into the irradiation chamber 8. The energy of the ion beam 10 is spread out there by means of an energy filter 20 and hits the donor substrate 12 to be irradiated. Alternatively, the energy filter 20 may be disposed in a separate vacuum chamber closable with valves within the irradiation chamber 8 or immediately adjacent to the irradiation chamber 8.

The substrate holder 30 need not be stationary, but may optionally be provided with a device for moving the donor substrate 12 in x-y (in the plane perpendicularly to the sheet plane). Another useful substrate holder 30 is also a wafer wheel on which the donor substrates 12 to be implanted are fixed and which turns during the implantation. It is also possible to move the substrate holder in beam direction (z direction). In addition, the substrate holder 30 may optionally be provided with a heater or cooler.

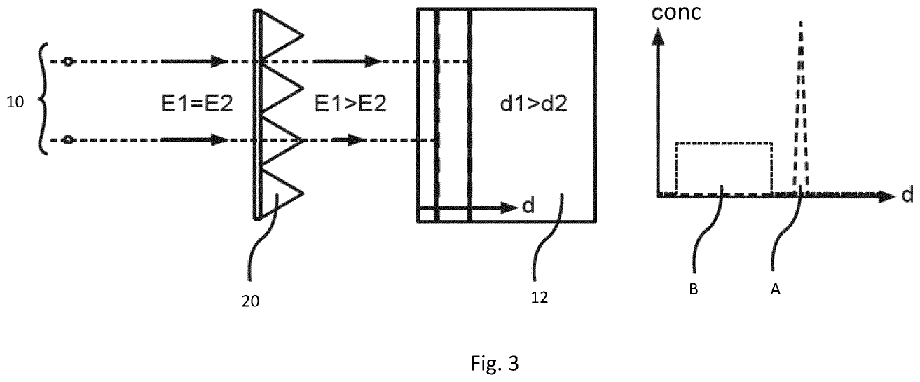

The basic principle of the energy filter 20 is shown in FIG. 3. The energy of the single-energy ion beam 10 is modified as it passes through the energy filter 20 configured as a microstructured membrane, depending on the site of entry. The resulting energy distribution of the ions of the ion beam 10 leads to modification of the depth profile of the implanted substance in the matrix of the donor substrate 12. E1 denotes the energy of a first ion, E2 denotes the energy of a second ion, conc denotes the dopant concentration, and d denotes the depth in the donor substrate 12. The diagram shows the typical Gaussian distribution on the right with reference sign A, which arises without use of an energy filter 20. By contrast, reference sign B shows, by way of example, a rectangular distribution that can be achieved when an energy filter 20 is used.

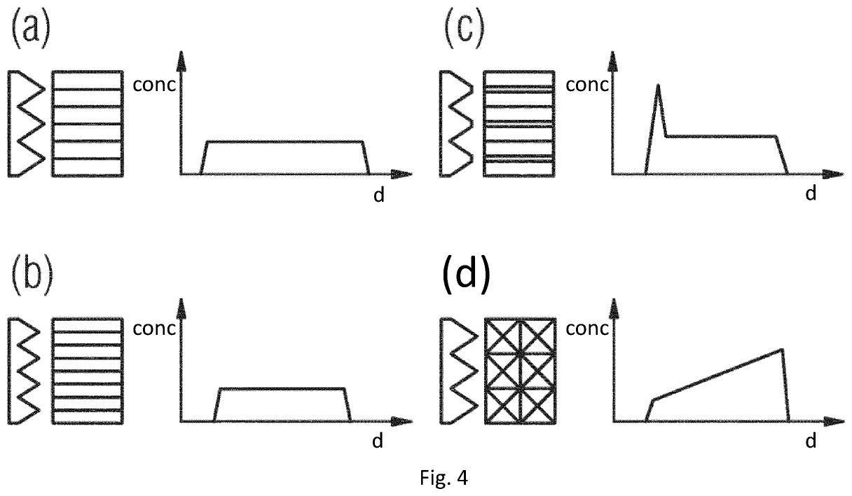

The layouts or three-dimensional structures of energy filters 20 that are shown in FIG. 4 show the basic options for creating a multitude of dopant depth profiles by means of energy filters 20. conc again denotes the dopant concentration, and d again denotes the depth in the donor substrate 12. The filter structure profiles may in principle be combined with one another in order to obtain new filter structure profiles and hence new dopant depth profiles.

Such energy filters 20 are generally produced from silicon. They have a thickness of between 3 μm and 200 μm, preferably between 5 μm and 50 μm, and more preferably between 7 μm and 20 μm. They may be held in a filter frame (not shown). The filter frame may be accommodated exchangably in a filter holder (not shown).

For the preferred formation of an n-doped first layer 21, implantation with ions of nitrogen or phosphorus is particularly suitable, whereinas, for a p-doped layer, implantation with ions of boron or aluminum is particularly suitable.

In the working example of the method step of doping the first layer 21 which is shown in FIG. 5, the ions are implanted into the donor substrate 12 from a front side of the donor substrate 12. The face of the donor substrate 12 that faces the ion beam is referred to hereinafter as outer face 23. The short black solid arrow indicates the ions of minimum energy transmitted through the energy filter 20, and the long black solid arrow indicates the ions of maximum energy transmitted through the energy filter 20. The resultant dopant profile in the A-A′ section is shown on the right in the coordinate system. conc represents the dopant concentration. The dopant profile is based on the configuration of the donor substrate 12 according to FIG. 1 and is approximately uniform across the entire first layer 21. The first layer 21 extends from the outer face 23 of the donor substrate 12 that faces the ion beam 10 up to a particular doping depth T, followed by a remaining portion 22 of the donor substrate 12 which is unaffected by the ion implantation by energy filter.

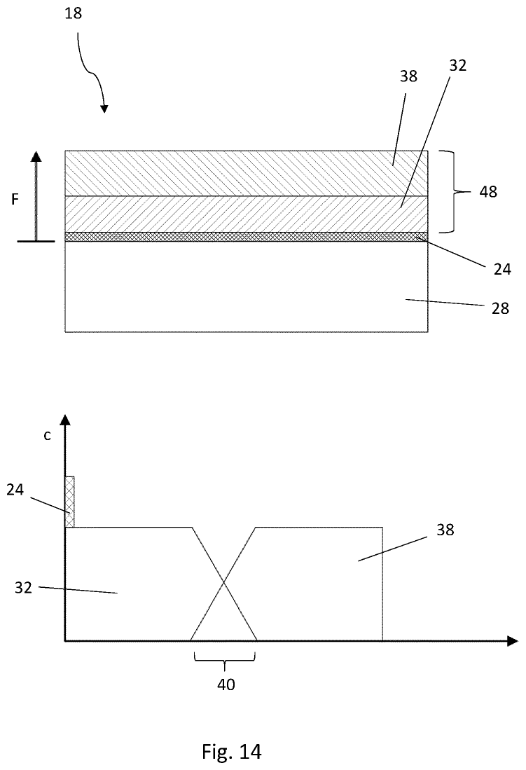

The thickness of the first layer 21 preferably corresponds substantially to a previously ascertained thickness of the active layer in the later semiconductor component or to a combination of active layer plus a field stop layer or to a combination of active layer plus a field stop layer and a superficial functional zone. The total thickness of the first layer 21 is thus determined by the nature and in particular by the voltage class of the semiconductor component to be produced. The higher the voltage class, the thicker the first layer 21. For particularly high voltage classes, reference is made to FIG. 14 and the accompanying description.

The thickness of the first layer 21 is preferably between 3 and 15 μm. This corresponds to the doping depth T which is currently viably possible for the abovementioned preferred ion types in SiC.

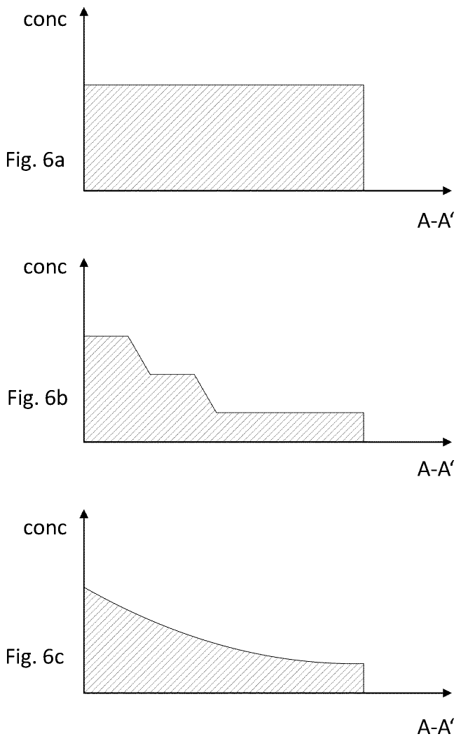

FIGS. 6a to 6c show possible preferred dopant profiles in the first layer 21 of the donor substrate 12.

In principle, the doping of the first layer 21 affords p or n doping with a dopant concentration (conc) or defect concentration in the first layer 21 of 1E15 cm⁻³ to 5E17 cm⁻³.

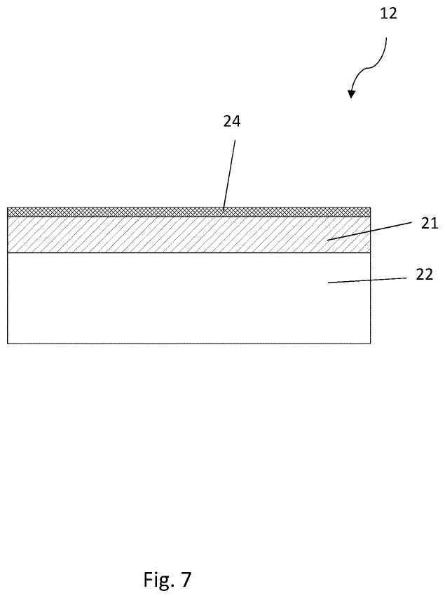

FIG. 7 shows the result of the optional step of creating a contact layer 24 or applying a contact layer 24 to the surface of the first layer 21 in a surface region of the first layer 21.

Preference is given to creating the contact layer 24 by ion implantation into the first layer 24. The contact layer 24 has a thickness of only 10 nm up to 1 μm. For the implantation, preference is given to using ions of P, N or Al (without an energy filter).

The dopant concentration in the contact layer 24 is preferably at least 100 times, more preferably at least 1000 times, more preferably at least 10 000 times, even more preferably at least 100 000 times, greater than an average dopant concentration in the remainder of the first layer 21 or in the first layer 21.

The dopant concentration in the contact layer 24 is preferably more than 1E17 cm⁻³, more preferably more than 1E19 cm⁻³.

It is also possible to apply a thin contact layer 24, for example of a few nanometers in thickness, to the first layer 21. This is accomplished, for example, by sputtering deposition, vapor deposition or a CVD deposition method. The contact layer 24 need not be completely covering; it may also consist of nanoparticles.

Simultaneously with or after application of the contact layer 24, a further treatment of the surface may take place, for example physical etching.

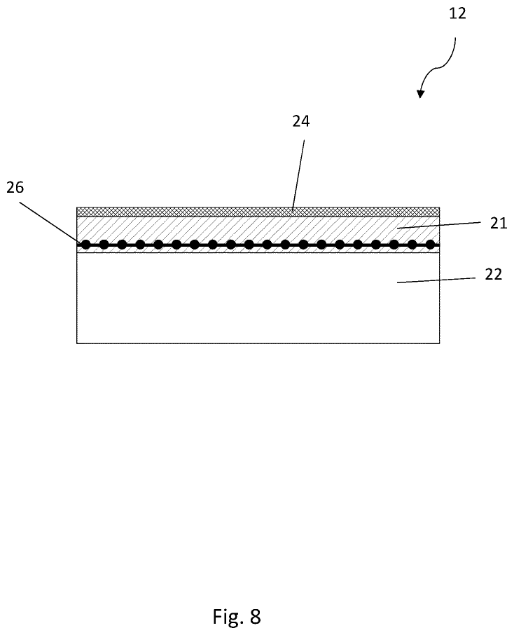

In the next step, according to FIG. 8, an intended breakage site 26 is created in the donor substrate 24. The intended breakage site 26, in the example of FIG. 8, is in the region of the first layer 21, preferably in an end region of the first layer 21 close to the predetermined doping depth T, wherein the intended breakage site 26 is remote from the doping depth T and hence from the end of the first layer 21 by preferably not more than 1 μm, more preferably not more than 500 nm, more preferably not more than 100 nm. Especially in the case of rectangular profiles with a declining flank, the intended breakage site 26 should still be in the region of the plateau.

The intended breakage site 26 is preferably created by ion implantation of split-triggering ions, which are shown schematically as black dots in FIG. 8. No energy filter is used here. According to FIG. 8, the split-triggering ions are introduced over the entire width of the donor substrate 12. The split-triggering ions are preferably selected from the following: H, H₂, He, B. The split-triggering ions are high-energy ions having energy between 0.5 and 10 MeV, preferably between 0.5 and 5 MeV, more preferably between 0.5 and 2 MeV. For hydrogen, in the case of an ion energy of 0.6 MeV, the intended breakage site 26 is formed at a depth of about 5 μm, in the case of an ion energy of 1.0 MeV at a depth of about 10 μm, and in the case of an ion energy of 1.5 MeV at a depth of about 20 μm.

A particle dose of the split-triggering ions is preferably in each case between 1E15 cm⁻² and 5E17 cm⁻². The energy spread (ΔE/E) of the ion beam of the split-triggering ions is preferably less than 10⁻², more preferably less than 10⁻⁴. In the implantation of the split-triggering ions, it is advantageous when the temperature in the donor substrate 12 remains below 300° C., preferably below 200° C. For this purpose, the chuck on which the donor substrate 12 lies is optionally cooled.

With these parameters, a doping profile having a sharp peak is created (see the Gaussian distribution identified by A in FIG. 3). In this way, it is ensured that the intended breakage site 26 has high doping distributed over an extremely small thickness. The variation in the range of the ions in the donor substrate 12 (longitudinal straggling a), depending on the primary energy of the ion beam, is only between 100 nm and 500 nm, preferably between 200 nm and 400 nm.

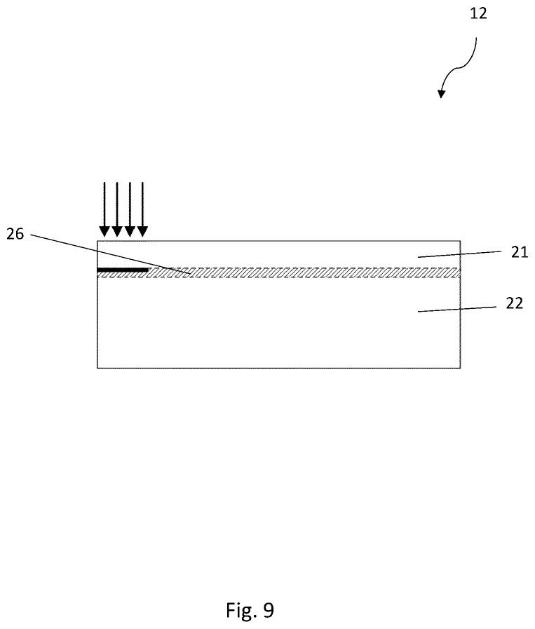

Alternatively, as shown in FIG. 9 by the arrows and the horizontal black bar, the split-triggering ions can be introduced only over part of the width of the donor substrate 12, preferably only in one or both edge regions of the donor substrate 12. In this way, the intended breakage site 26 is predefined in sections.

As an alternative to ion implantation, the intended breakage site 26 may also be formed by electron irradiation or laser irradiation.

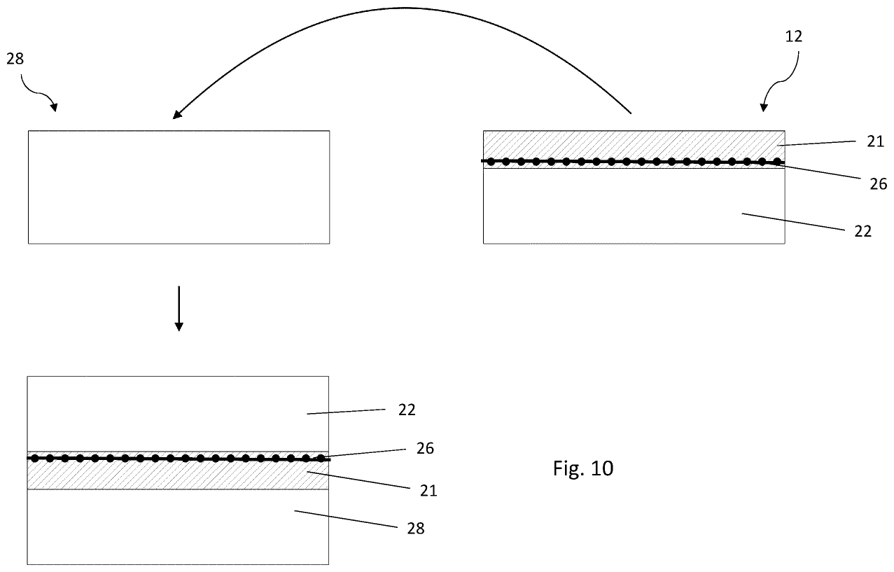

Subsequently, the donor substrate 12 is bonded to the acceptor substrate 28 with the side of the first layer 21 forward, as shown in FIG. 10. The first layer 21 is thus disposed in a region between the acceptor substrate 28 and the remaining portion 22 of the donor substrate 12. Whether the donor substrate 12 is moved toward the acceptor substrate 28 for the establishing of the bond, as shown in FIG. 10 by the curved arrow, which also indicates that the donor substrate 12 is turned over, or the acceptor substrate 28 is moved toward the donor substrate 12 is immaterial.

The intermediate result of the bonding process is shown bottom left in FIG. 10. It would likewise be possible to reverse the layer sequence, for example if the acceptor substrate 28 was moved toward the donor substrate 12.

A whole series of materials are possible for the acceptor substrate 28. The acceptor substrate 28 is preferably thermally stable up to at least 1500° C. and has a coefficient of linear expansion that deviates by not more than 20%, ideally by not more than 10%, from the coefficient of linear expansion of SiC. Suitable examples for the material of the acceptor substrate 28 are polycrystalline SiC or graphite.

FIGS. 9 and 10 do not show the contact layer 24 in each case, but it is preferably present. In that case, the bond between donor substrate 12 and acceptor substrate 28 is established via the contact layer 24, resulting in the following sequence: acceptor substrate 28, contact layer 24, remaining portion of first layer 21 or first layer 21, remaining portion 22 of the donor substrate 12.

A low-resistance bond is preferably established by a thermal treatment of the substrate obtained as the intermediate result at a temperature of between 800° C. and 1600° C., more preferably between 900° C. and 1300° C.

The step of establishing the bond may be preceded by a pretreatment of at least one, preferably both, of the surfaces to be bonded, especially a wet-chemical treatment, plasma treatment or ion beam treatment. A treated surface may also be the contact layer 24. Also conceivable is application of a thin layer, of a few nanometers in thickness, for production of a later low-resistance bond of acceptor substrate 28 and donor substrate 12. In principle, an extremely low-resistance contact and a high-temperature-resistant bond between acceptor substrate 28 and donor substrate 12 is important.

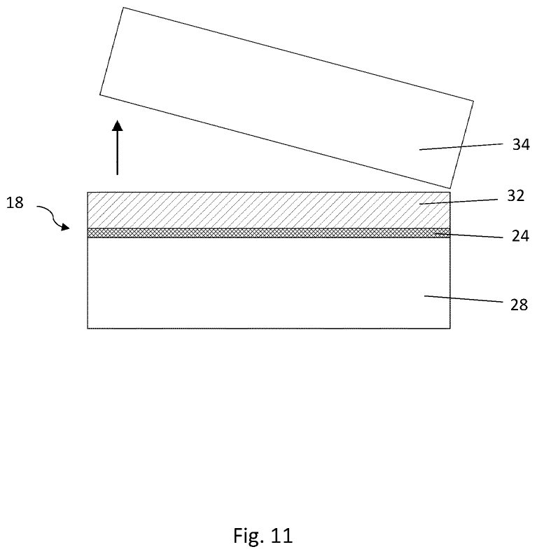

FIG. 11 shows a schematic of the step of splitting the donor substrate 12 in the region of the intended breakage site 26, which creates a pretreated composite substrate 18 comprising the acceptor substrate 28 and a doped layer 32 bonded thereto, wherein the doped layer 32 comprises at least a section of the first layer 21 of the donor substrate 12. The portion 34 of the donor substrate 12 split off from the acceptor substrate 28 is removed.

The splitting of the donor substrate 12 is preferably triggered by a thermal treatment of the composite substrate 18 at a temperature between 600° C. and 1300° C., preferably between 750° C. and 1200° C., more preferably between 850° C. and 1050° C. In one embodiment (see FIGS. 8 and 9), gas bubbles are formed owing to the implanted ions, which coalesce and lead to splitting.

Alternatively, external forces may be exerted on the composite substrate 18, such that the donor substrate 12 breaks up at the intended breakage site 26. A combination of thermal treatment and external forces may also be necessary or helpful. Especially when ions have been introduced into the donor substrate 12 only in sections, the exertion of external forces is unavoidable.

If both the establishing of the bond and the splitting of the donor substrate 12 are effected by a thermal treatment, the two steps can under some circumstances be performed simultaneously.

It is preferable when, immediately after the splitting, the surface of the donor substrate 12 formed is oriented exactly perpendicularly to the c direction of the crystal structure. Certain incorrect orientations and variances of up to 0.5° may occur because of the splitting process.

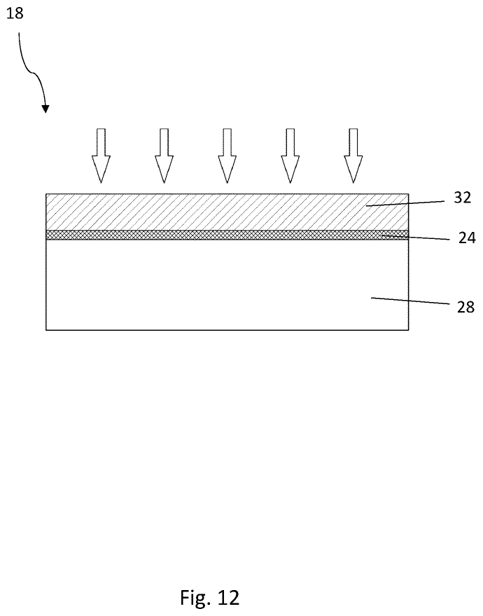

Moreover, as shown schematically in FIG. 12 by the arrows, after the splitting step, there may be an aftertreatment of the first surface of the composite substrate 18 in the region of the intended breakage site 26, especially by polishing and/or removing defects.

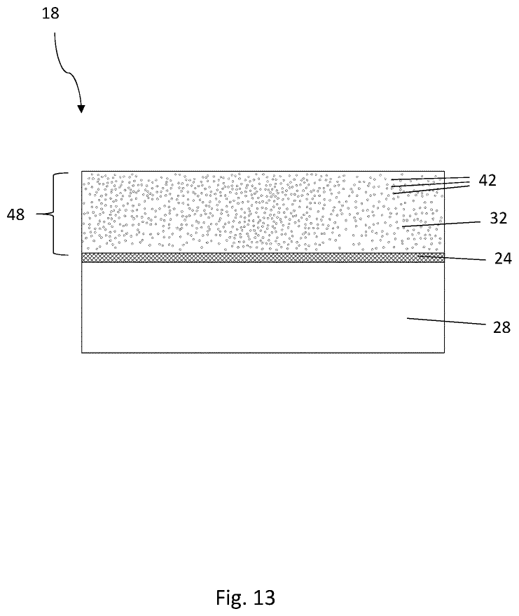

Implantation defects 42 that are shown schematically in FIG. 13 may finally be annealed in the doped layer 32 of the pretreated composite substrate 18 at temperatures of preferably between 1500° C. and 1750° C. This is preferably effected during the later component processing in heat treatment steps for annealing of low-energy implantations, e.g. source-drain contact implantation, channel implantation, p-JFET implantation etc.

It is also conceivable that the step of annealing the implantation defects 42 is already conducted during the splitting-off of the portion 34 of the donor substrate 12 and/or during the forming of the bond between donor substrate 12 and acceptor substrate 28 if correspondingly high temperatures are used and the radiation defects can be annealed in that way.

In a departure from the description so far, the step of producing the bond between donor substrate 12 and acceptor substrate 28 may also proceed in two stages. First of all, for example, a bonding process may take place with low bonding energy at low temperature and then, in a subsequent second substep, consolidation to produce a bond with high bond strength or bond energy at high temperature and low contact resistance. The solidification may, for example, also be effected during or after the splitting, during or after the surface treatment of the composite substrate, or during or after the annealing of implantation defects.

The pretreated composite substrate 18 thus produced, which serves as a basis for further processing into an electronic semiconductor component, is shown once again in FIG. 13. It comprises the acceptor substrate 28 and the doped layer 32 of monocrystalline SiC bonded thereto, wherein the doped layer 32 preferably includes the implantation defects 42 (radiation defects). It may also have the contact layer 24 between acceptor substrate 28 and doped layer 32.

The doped layer 32 preferably has a thickness of 3 μm to 30 μm, more preferably of 3 μm to 15 μm. It is preferably composed of SiC of the 4H, 6H or 3C polytype. The surface of the doped layer 32 preferably has a deviation of less than 0.5° from a perpendicular to the c direction. The doped layer 32 preferably has p or n doping with a dopant concentration or defect concentration of 1E15 cm−3 to 5E17 cm−3. The doped layer 32 was preferably doped with ions of one of the following elements as dopant: N, P, B or Al.

The dopant depth profile of the doped layer 32 preferably results essentially from a reversal of the dopant depth profile of the first layer 21 in the donor substrate 12.

The doped layer 32 may thus, for example, have a substantially constant dopant depth profile.

It is likewise possible for the doped layer 32 to have a dopant depth profile that rises in steps in the direction towards the acceptor substrate 28, wherein the steps are formed in a region of the doped layer 32 facing the acceptor substrate 28 by up to 40%, preferably up to 30%, of the total depth of the doped layer 32.

The doped layer 32 may also give a dopant depth profile that rises continuously in the direction towards the acceptor substrate 28.

The implantation defect profile substantially follows the implanted extrinsic atom concentration depth profile.

The acceptor substrate 28 is thermally stable up to at least 1500° C. and has a coefficient of linear expansion that deviates by not more than 20%, preferably by not more than 10%, from the coefficient of linear expansion of SiC. The acceptor substrate 28 is more preferably formed from polycrystalline SiC or graphite.

FIG. 14 shows an alternative configuration of the pretreated composite substrate 18 in cross section and, below that, a dopant concentration profile along the section of the composite substrate 18 corresponding to arrow F. This is particularly suitable for the production of very highly blocking components, e.g. >600 V.

In this case, the pretreated composite substrate 18, in addition to the doped layer 32, has a supplementary doped layer 38 of monocrystalline SiC. In a transition section between the doped layer 32 and the supplementary doped layer 38, there is preferably an overlap region 40 of the respective dopant depth profiles.

In the embodiment shown in FIG. 13, the active layer required (drift zone, voltage-absorbing layer) in the later semiconductor component is formed solely by the doped layer 32 and hence simultaneously by the first layer 21 or a (preferably large) portion of the first layer 21 in the donor substrate 12.

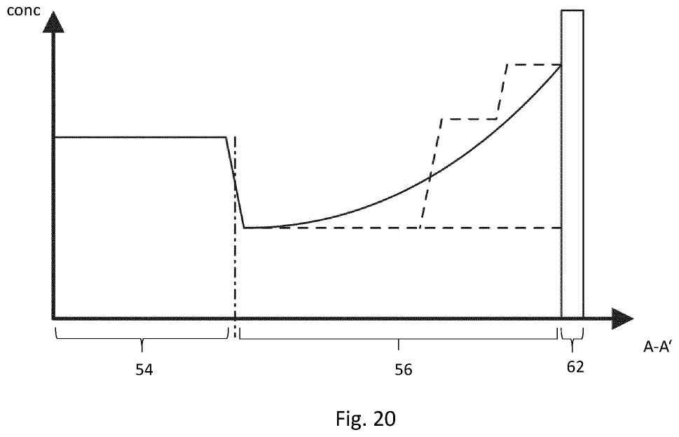

By contrast, the active layer in embodiments as in FIG. 14 is formed by a combination of doped layer 32 and the supplementary doped layer 38. While a substantially constant cumulative dopant profile results from superimposition of the two component profiles in FIG. 14, it is also possible for any other dopant profiles to be formed by the juxtaposition and partial overlapping of the dopant profiles in doped layer 32 and supplementary doped layer 38. It is thus possible for the combined overall dopant profile composed of the combination of the two dopant depth profiles of the doped layer 32 and of the supplementary doped layer 38 also to be a profile that rises stepwise toward the acceptor substrate 28 or a profile that rises continuously toward the acceptor substrate 28. Further particularly preferred dopant profiles are described in detail with reference to FIG. 20.

In each of these embodiments, reference number 48 refers to the first section of the donor substrate 12 that remains in each case as part of the composite substrate 18 after the splitting-off. This first section 48 may either be composed solely of the doped layer 32 if there is no supplementary doped layer 38 (FIG. 13), or of a combination of the doped layer 32 and the supplementary doped layer 38 (FIG. 14, FIG. 20).

Such combined profiles are obtained in that the intended breakage site 26 in the donor substrate 12 is created not within the first layer 21 but within the remaining portion 22 of the donor substrate 12 that has not been doped by ion implantation into the donor substrate 12.

After the splitting at the intended breakage site 26 as in FIG. 11, the doping of the supplementary doped layer 38 can then be conducted proceeding from the side remote from the acceptor substrate by further ion implantation by means of energy filters. The statements relating to ion implantation by means of energy filters that have been made above with regard to FIG. 2 to FIG. 6 are identically applicable to the ion implantation into the supplementary doped layer 38. The thickness of the supplementary doped layer 38 is generally between 3 and 15 μm. Total thicknesses of the active zone doped by ion implantation of up to 30 μm are thus obtained.

In principle, it is possible by the method according to an aspect of the invention to produce two or more composite substrates 18, or even a multitude of composite substrates 18, from a donor substrate 12, provided that the donor substrate 12 from FIG. 1 is at least twice as thick as the thickness of the doped layer 32 required in the composite substrate 18. This effect is particularly high in the case of a thick wafer bar as donor substrate 12. In this way, it is possible to save considerable costs in production. This is shown schematically in FIG. 15.

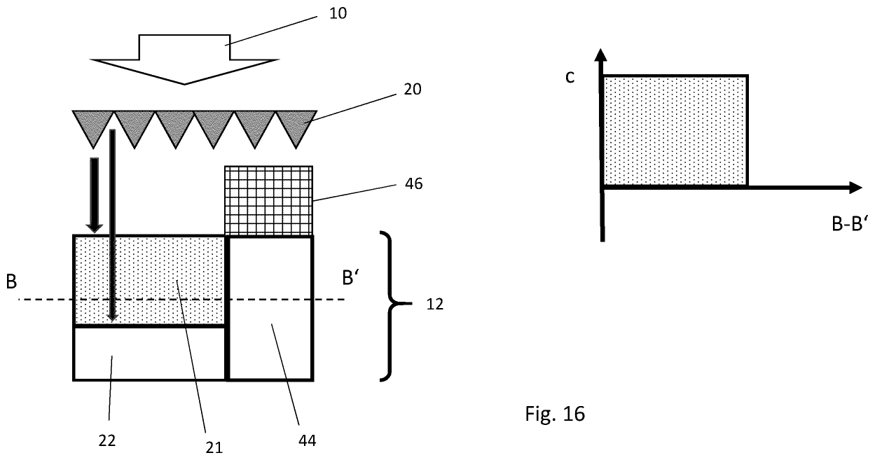

As shown in FIG. 16, in the ion implantation by means of energy filters 20 into the first layer 21 of the donor substrate 12 (and/or into the supplementary doped layer 38 of the composite substrate 18), a mask 46 may be used in order to create one or more undoped regions 44 in the first layer 21 of the donor substrate 12 (and/or in the supplementary doped layer 38 of the composite substrate 18).

The composite substrate 18 may become a finished semiconductor component 50 as a result of further steps, for example as a result of the implanting of further active areas, the creating of oxides, the depositing of gate electrodes, contacts, wires or vias etc.

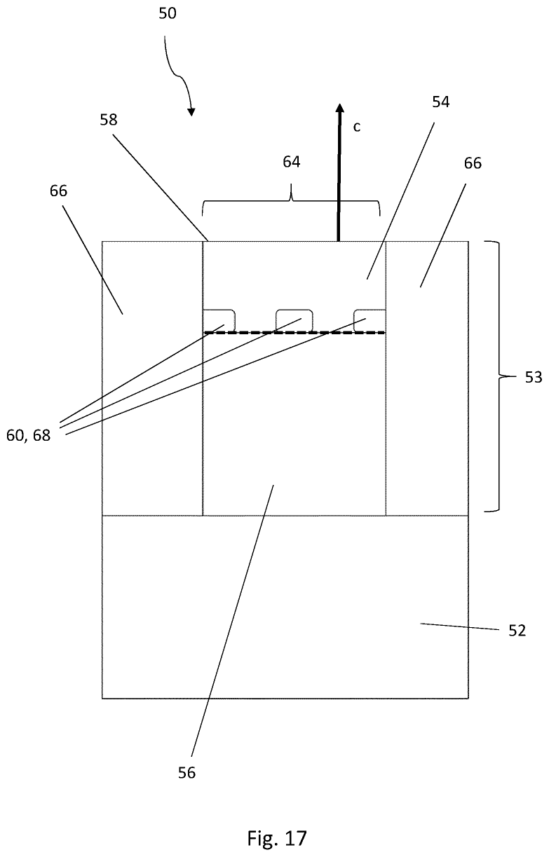

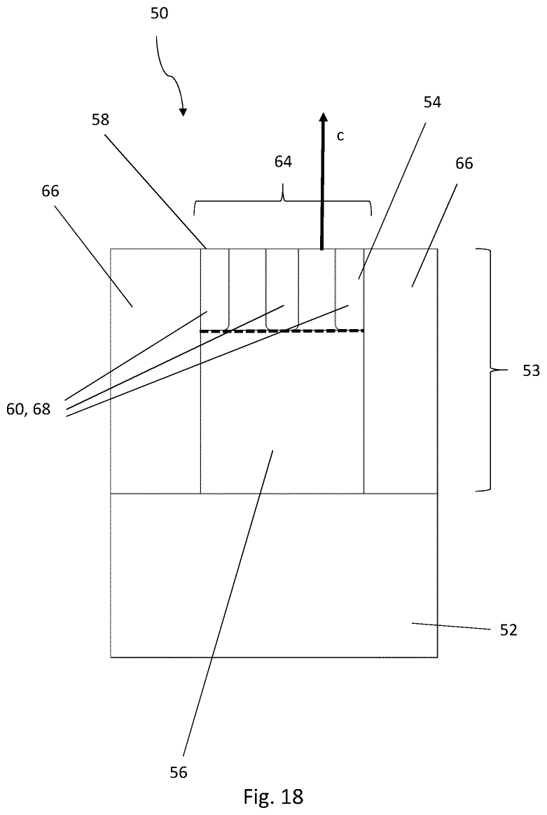

Two fundamental base structures of electronic semiconductor components 50 according to an aspect of the invention are shown in FIG. 17 and FIG. 18.

The first base structure from FIG. 17 comprises a carrier substrate 52, which generally corresponds to the acceptor substrate 28 of the pretreated composite substrate 18. The carrier substrate 52 generally consists of a highly doped material and is generally field-free.

A crystal 53 of SiC is mounted on the carrier substrate 52. This crystal 53 generally corresponds to the first section 48 of the donor substrate 12 of the pretreated composite substrate 18.

On the side remote from the carrier substrate 52, the crystal 53 has a first surface 58. This first surface 58 deviates by less than 0.5°, preferably by less than 0.3°, more preferably by less than 0.1°, most preferably not at all, from a direction perpendicularly to the c direction (arrow c) of the crystal structure of the crystal 53.

The electronic semiconductor component 50 comprises an active component region 64 having a first zone 54 in the region of the first surface 58, and a second zone 56 that follows the first zone 54 in depthwise direction.

The first zone 54 comprises a near-surface shielding structure 60 or JFET structure in a region comprising at least subsections of the first surface 58 of the crystal 53. The shielding structure or J-FET structure is characterized by a p⁺/n junction which is interrupted in one direction, i.e. a p+ area is formed in areas (not continuously) and is generally not depletable. The regions with p⁺ doping are indicated by reference numerals 68.

The second zone 56 comprises or consists of a voltage-absorbing layer (also called drift zone or active layer). The junction between the first zone 54 and the second zone 56 is identified by the dotted line. The thickness of the second zone 56 is preferably between 2 μm and 50 μm.

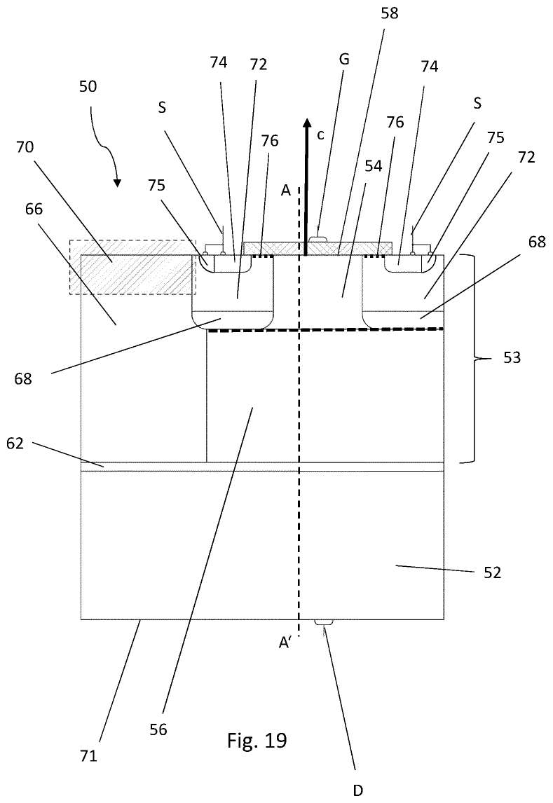

As apparent from FIGS. 19 to 25, the semiconductor component 50 additionally comprises, at the junction between the second zone 56 and the carrier substrate 52, a field-free contact zone or field stop zone 62. This field stop zone 62 generally corresponds to the contact layer 24 of the pretreated composite substrate 18. The field-free contact zone or field stop zone 62 has a vertical thickness of not more than 2 μm, preferably not more than 1 μm.

An inactive edge region 66 laterally surrounds the first zone 54 and the second zone 56 substantially completely.

The second base structure of the semiconductor component 50 according to an aspect of the invention which is shown in FIG. 18 corresponds to the base structure from FIG. 17 in significant portions. Identical reference numerals denote identical elements. The difference is that the p+ areas 60 are not buried areas, but are formed continuously up to the first surface 58.

All the p-doped shielding structures 60, irrespective of the particular type of semiconductor component 50, have multiple features in common. The shielding structures 60 parallel to the first surface 58 are not continuous but periodically interrupted. The distances, as a result of the distance from the first surface 58, are such that the maximum tolerable field strength at the first surface 58 is not reliably exceeded in the “open” regions in blocking operation. The shielding structures 60 are connected either directly or via wires (third dimension, not shown) to the source potential, gate potential or anode potential. The shielding structures 60 are either embedded in isolated form (apart from the electrical connection) in an n-doped area, or they are formed proceeding from the first surface 58 as doped areas with a high aspect ratio. The typical depths of the p-n junction are between 500 nm and 3.0 μm. The shielding structures 60 are sufficiently highly doped that the areas are not depleted even in the case of maximum blocking voltage.

The spatial delimitation between the first zone 54 and second zone 56 which is represented by the dashed line in FIG. 17 and FIG. 18 is typically at the point wherein the p-doped areas 68 end in depthwise direction of the crystal 53. The junction in the present description is typically defined as being parallel to the first surface 58.

It is also true overall in respect of the uppermost crystal layer in the second zone 56 that it is oriented substantially perpendicularly to the c direction (arrow c) of the crystal structure.

The working examples of the electronic semiconductor component 50 that are shown in FIGS. 19 to 26 show merely a detail of the semiconductor component 50. The respective right flank should be regarded as a broken-off flank.

FIG. 19 shows a vertical power semiconductor component 50 in the form of a planar MOS transistor. The inactive edge region 66, apart from an optional near-surface edge structure 70, is preferably nominally undoped. Reference numeral 52 still refers to the carrier substrate, reference numeral 53 still refers to the SiC crystal, reference numeral 54 still refers to the first zone, reference numeral 56 still refers to the second zone, reference numeral 62 still refers to the field stop zone, reference numeral 52 still refers to the carrier substrate, and reference numeral 68 still refers to the p⁺ areas of the shielding structure. A metal contact 71 has been applied to the underside of the carrier substrate 52. G denotes the gate electrode, S denotes the source electrode, and D denotes the drain electrode. Reference numeral 72 denotes p areas (p well), and reference numeral 74 denotes n+ areas. Reference numeral 75 denotes further p+ areas. The first surface 58 of the crystal 53 here is flat and preferably extends over the entire width of the semiconductor component 50. Gate oxides are explicitly not considered to be part of the first surface 58.

What is essential is that the first surface 58 is oriented substantially perpendicularly to the c direction (arrow c) of the crystal structure of the crystal 53. Slight variances of up to 0.5° are tolerable under some circumstances. It also follows that the channel region 76 (shown by dotted lines) that runs parallel to the first surface 58 of the crystal 53 deviates by less than 0.5°, preferably by less than 0.3°, more preferably by less than 0.1°, most preferably not at all, from a direction perpendicularly to the c direction of the crystal structure of the crystal 53.

As well as the embodiment of the planar MOSFET shown, the person skilled in the art is also aware of many other configurations of a planar MOSFET that are likewise to be encompassed by an aspect of the invention, provided that the first surface 58 of the crystal 53 is oriented substantially perpendicularly to the c direction (arrow c) of the crystal structure of the crystal 53.

The dopant profile (conc) of the semiconductor component 50 from FIG. 19, which is shown in FIG. 20, has a profile rising continuously in depthwise direction in the region of the second zone 56, as already described further up with regard to the pretreated composite substrate 18. Alternatively, the dopant profile, in the region of the second zone 56, may also be constant or be a profile that rises stepwise in the end region of the second zone 56, as indicated by the dashed lines. With reference to FIGS. 6a to 6c, a description has already been given above of the way in which such dopant profiles can be obtained.

It is preferable that, in addition, in the region of the first zone 54, the dopant profile has a plateau higher than the doping in the adjoining region of the second zone 56. In general, the region of the first zone 54 and the region of the second zone 56 are each n-doped. Preferably, the dopant concentration in the n-doped region of the first zone 54 is higher by a factor of 1.5 to 100, more preferably by a factor of 2 to 10, than in an n-doped region of the second zone 56 that faces the first zone 54. The declining flank of the doping profile is generally not completely vertical.

In the p+ areas 68 of the first zone 54, doping that deviates from the profile described is of course obtained. A dopant concentration in a p+ area 68 of the first zone 54 is preferably higher by a factor of 2 to 1000, more preferably by a factor of 50 to 1000, than a dopant concentration in an n-doped region of the second zone 56 that faces the first zone 54.

In a departure from FIG. 20, it is also possible that the doping profile in the first zone 54 and that in the second zone 56 adjoin one another substantially seamlessly. This is self-explanatory if the first zone 54 and the second zone 56 have been doped by means of the same implantation operation (as doped layer 32 in the donor substrate 12). However, this is also possible if the first zone 54 has first been doped in a subsequent implantation operation (for example as supplementary doped layer 38).

The doping profiles of the second zone 56 from FIG. 20 are likewise applicable to the second zones 56 of all the other semiconductor components 50 described.

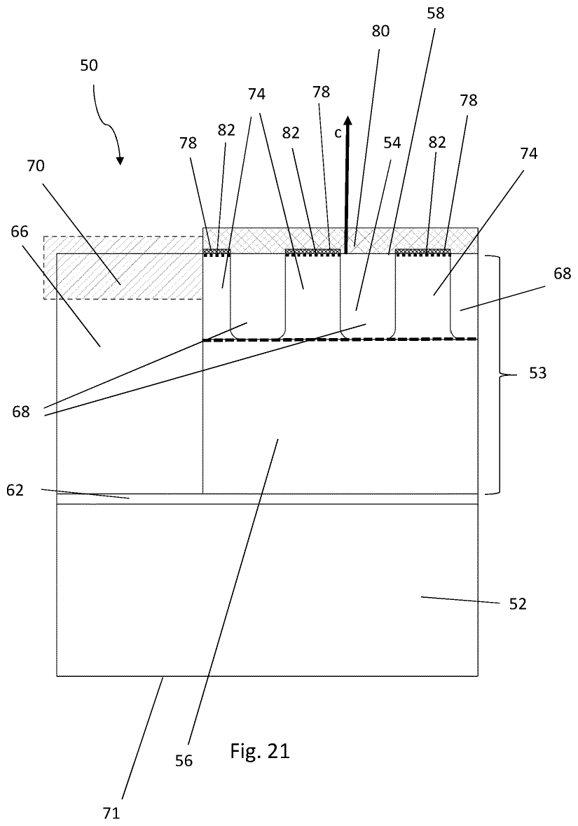

FIG. 21 shows a vertical power semiconductor component 50 in the form of a vertical merged PIN Schottky diode (MPS diode). Identical reference numerals denote identical elements to those in FIG. 19.

The p+ areas 68 run here through the entire depth of the first zone 54 from the first surface 58 up to the junction with the second zone 56. The first surface 58 is again continuous over the entire width of the semiconductor component 50, and is oriented substantially perpendicularly to the c direction (arrow c) of the crystal structure of the crystal 53. Reference numeral 78 denotes the Schottky material, and reference numeral 80 denotes a metal layer (anode). Metal contact 71 functions as cathode.

The Schottky junction 82 (shown by dotted lines) runs in a plane parallel to the first surface 58 of the crystal 53, and accordingly deviates by less than 0.5°, preferably by less than 0.3°, more preferably by less than 0.1°, most preferably not at all, from a direction perpendicularly to the c direction of the crystal structure of the crystal 53.

As well as the embodiment of the MPS diode shown, the person skilled in the art is also aware of many other configurations of an MPS diode that are likewise to be encompassed by an aspect of the invention, provided that the first surface 58 of the crystal 53 is oriented substantially perpendicularly to the c direction of the crystal structure of the crystal 53.

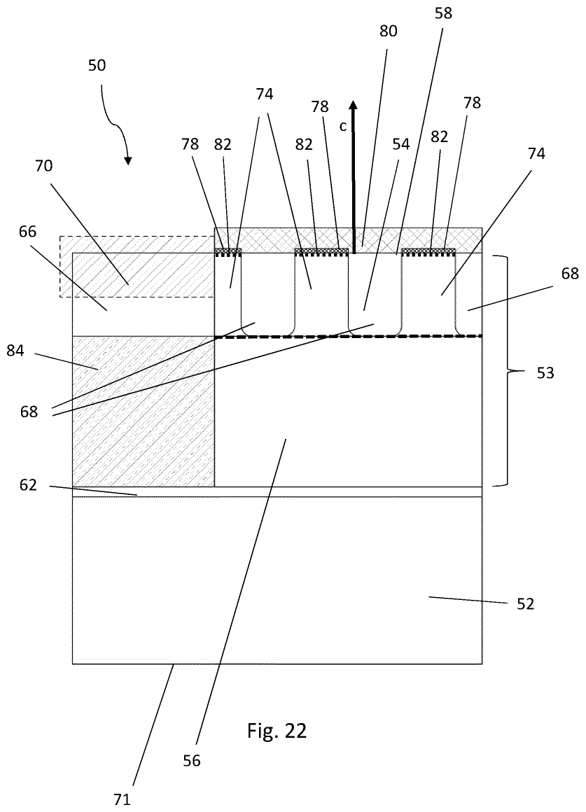

The MPS diode shown in FIG. 22 differs from the MPS diode from FIG. 21 in that the edge region 66, apart from any near-surface field-reducing edge structure 70 present, is substantially undoped from the first surface 58 onward and, substantially from a depth at which the second zone 56 commences up to a depth at which the field-free contact zone or field stop zone 62 lies, has been provided with the same dopant concentration as the second zone 56 or has been provided with a lower dopant concentration than the second zone 56, preferably with a lower dopant concentration by at least 20%, more preferably with a lower dopant concentration by at least 50%. This doped portion of the edge region 66 is identified by reference numeral 84.

There may also be such a doped region 84 in other configurations of the semiconductor component 50 as well.

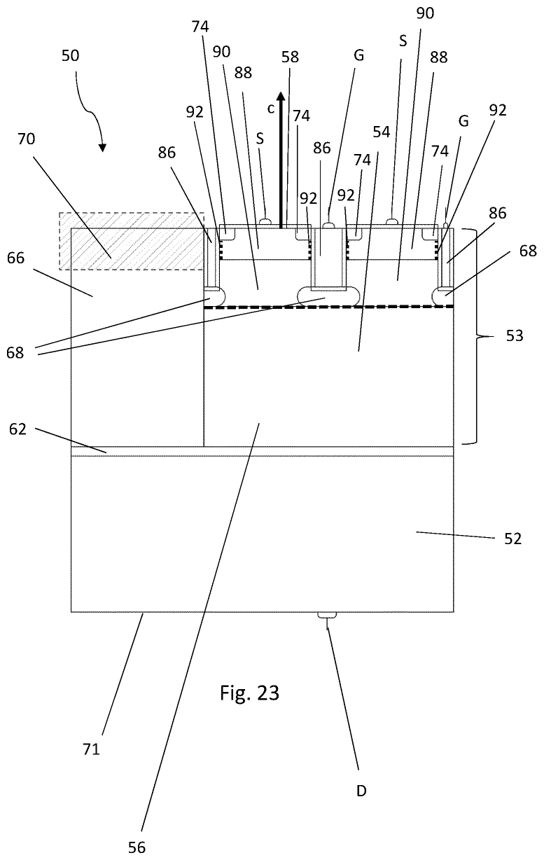

FIG. 23 shows a vertical power semiconductor component 50 in the form of a vertical trench MOSFET. Identical reference numerals denote identical elements to those in FIG. 19. Reference numeral 86 denotes a trench at least partly lined with a gate oxide, reference numeral 88 denotes p-doped regions, reference numeral 90 denotes n-doped regions, and reference numeral 92 denotes the respective channel region (shown by dotted lines).

The channel region 92 deviates by less than 0.5°, preferably by less than 0.3°, more preferably by less than 0.1°, most preferably not at all, from the c direction (arrow c) of the crystal structure of the crystal 53. The channel region 92 likewise deviates by less than 0.5°, preferably by less than 0.3°, more preferably by less than 0.1°, most preferably not at all, from a direction perpendicularly to the first surface 58 of the crystal 53. It is particularly preferable that the channel region 92 is arranged in an A plane of the crystal 53.

The first surface 58 in this example is interrupted, meaning that only subsections of the respective surface 58 that are arranged between the trenches 86 must fulfill the above criterion. But it is also conceivable that each trench 86, at its base, likewise comprises subsections of the crystal 53 with areas perpendicularly to the c direction of the crystal structure.

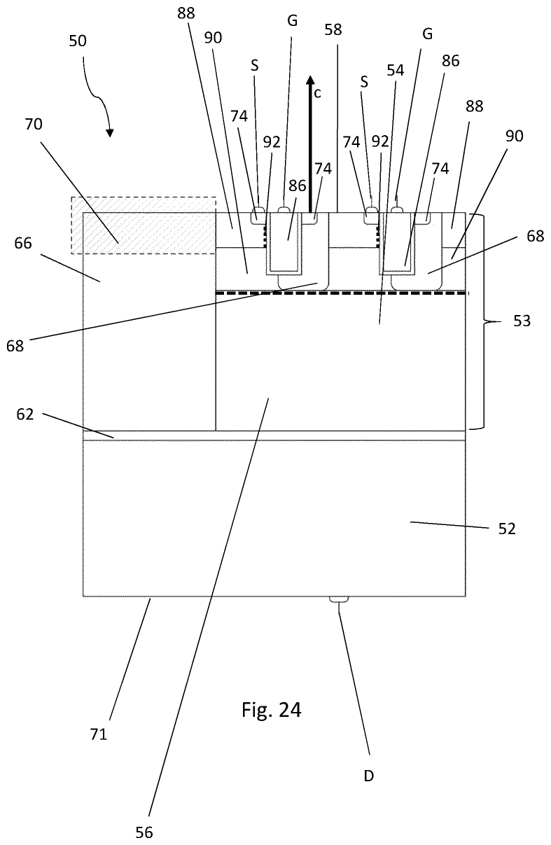

The embodiment of a vertical trench MOSFET shown in FIG. 24 differs from the embodiment according to FIG. 23 substantially by the arrangement of the p+ areas 68, which, in the present case, extend along a flank of the trenches 86 through the first zone 54 up to the first surface 58, and of the source electrodes S.

As well as the embodiments of the trench MOSFET shown, the person skilled in the art is also aware of many other configurations of trench MOSFETs that are likewise to be encompassed by an aspect of the invention, provided that the first surface 58 of the crystal 53 is oriented substantially perpendicularly to the c direction of the crystal structure of the crystal 53.

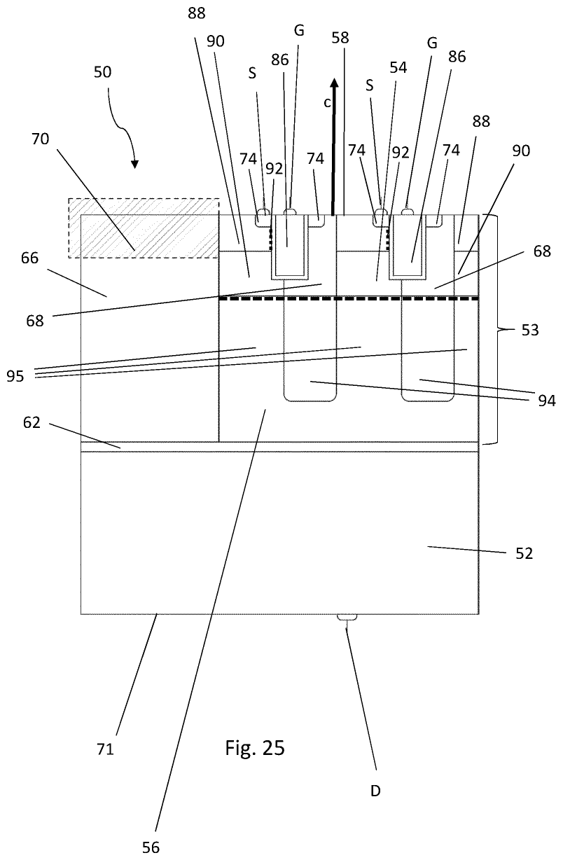

FIG. 25 shows a vertical power semiconductor component 50 in the form of a superjunction trench MOSFET. Identical reference numerals denote identical elements to those in FIG. 23. In addition to the structural elements already specified in that case, p-doped columns 94 are also formed in the second zone 56 beneath the p+ areas 68 of the first zone 54.

The p-doped columns 94 in the second zone 2 differ from the p+ areas 68 in the first zone 54 in that they are in the voltage-absorbing zone. This means that the p-doped columns 94 must be configured so as to be completely depletable. In other words, in the case of blocking, the spatial charge zone extends laterally both across the p columns and the n areas 95 in the second zone 56.

The level of doping and the depth of the p-doped columns 94 depend on the voltage class of the component 50. The p-doped columns 94 in the second zone 56 are preferably produced by masked energy-filtered implantation. For the superjunction structure shown in FIG. 25, it is particularly advantageous for the edge region 66 to be undoped.

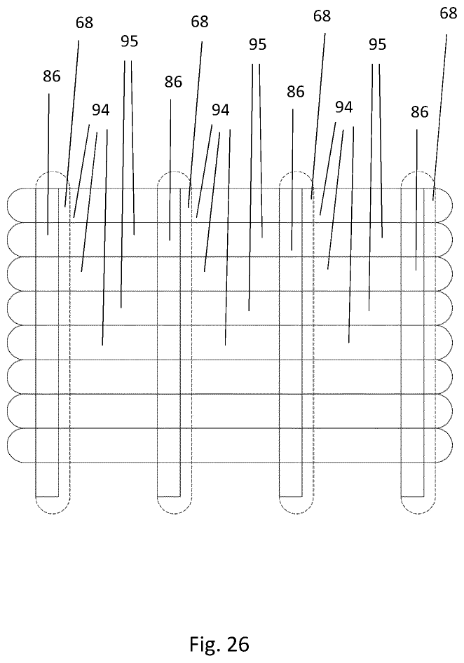

This results in two preferred embodiments for the layout of the superjunction MOSFET:
1. The gate trenches 86 and the p+ areas (shielding structures) 68 are executed as long trenches. The p-doped columns 94 in the second zone 56 follow these trenches, such that the section has the appearance as shown in FIG. 25.
2. The gate trenches 86 and the p+ areas (shielding structures) 68 are again executed as long trenches. In the projection onto the component surface, the p-doped columns 94 in the second zone 56 are arranged perpendicularly to the gate trenches 86 and the p+ areas 68; see the schematic top view from FIG. 26.

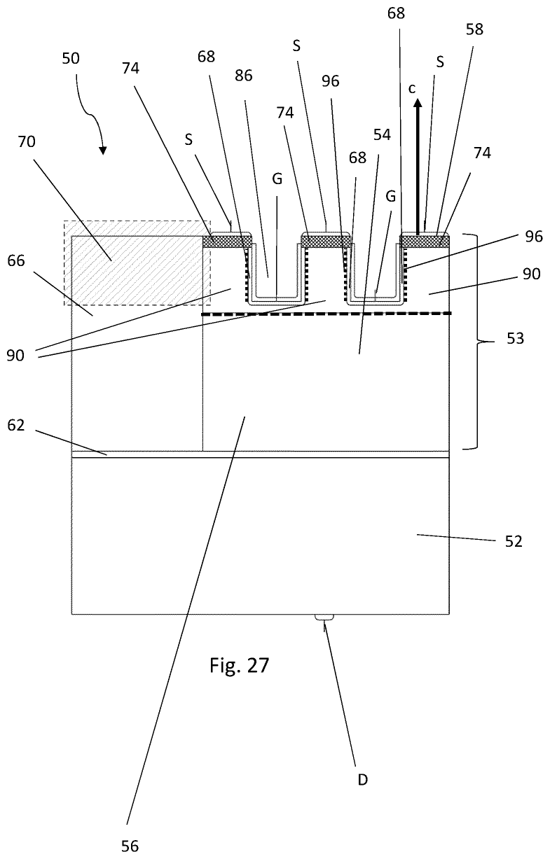

FIG. 27 shows a vertical power semiconductor component 50 in the form of a J-FET (junction field-effect transistor). Identical reference numerals denote identical elements or areas to those in the preceding figures. The p+ areas 68 run in a U shape around the likewise U-shaped gate contacts, and the relevant interfaces 96 between p+ and n are shown by dotted lines. These interfaces 96 run perpendicularly to the subsections of the first surface 58.

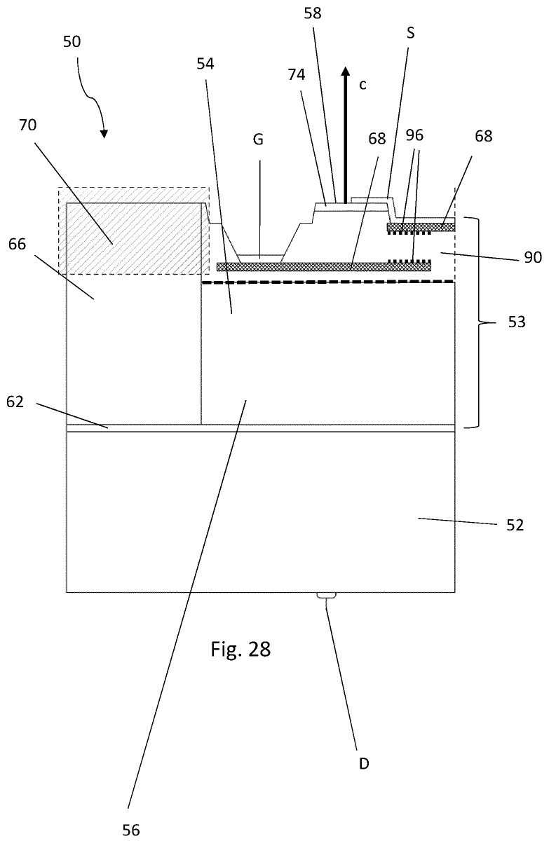

FIG. 28 shows another embodiment of a J-FET. Identical reference numerals denote identical elements or areas to those in the preceding figures. The interfaces 96 here run parallel to the subsections of the first surface 58.

As well as the base structures of the semiconductor components 50 that have been shown so far, the person skilled in the art is also aware of many other configurations of semiconductor components that are likewise to be encompassed by an aspect of the invention, provided that the first surface 58 of the crystal 53 is oriented substantially perpendicularly to the c direction of the crystal structure of the crystal 53.

As well as the above-described production method, it is also possible not to form a composite substrate 18, but to temporarily stabilize a crystal 53 from a thin layer of high-quality crystalline SiC material which is suitable for formation of components 50, and the surface of which is oriented substantially perpendicularly to the c direction of the crystal structure of the crystal 53, during the component production by means of a carrier, for example by means of temporary bonds, or to configure it in a completely self-supporting manner. In these cases, there is no need for a carrier substrate 52 in the finished component 50.

In the context of this description, “bonded” is understood to mean bonded directly or indirectly, i.e. with intermediate inclusion of a further element. A “bond” between two elements may also be direct or indirect.

1.-66. (canceled)

67. An electronic semiconductor component comprising a crystal made of monocrystalline SiC, wherein the orientation of at least subsections of a first surface of the crystal deviates by less than 0.5° from a direction perpendicularly to the c direction of the crystal structure of the crystal.

68. The electronic semiconductor component of claim 67, further comprising an active component region comprising:
a first zone having a near-surface shielding structure or JFET structure in a region comprising at least subsections of the first surface of the crystal;
a second zone having a voltage-absorbing layer, arranged on a side of the first zone remote from the first surface of the crystal and adjoining the first zone; and
a field-free contact zone or field stop zone arranged on a side of the second zone remote from the first zone.

69. The electronic semiconductor component of claim 68, wherein the first zone and the second zone are formed substantially on the basis of the crystal made of SiC.

70. The electronic semiconductor component of claim 68, wherein a thickness of the first zone is between 0.5 μm and 3.0 μm.

71. The electronic semiconductor component of claim 68, wherein a thickness of the second zone is between 2 μm and 50 μm.

72. The electronic semiconductor component of claim 68, wherein a dopant concentration in an n-doped region of the first zone is higher by a factor of 1.5 to 100 than a dopant concentration in an n-doped region of the second zone which faces the first zone.

73. The electronic semiconductor component of claim 68, wherein a dopant concentration in a p-doped area of the first zone is higher by a factor of 2 to 1000 than a dopant concentration in an n-doped region of the second zone which faces the first zone.

74. The electronic semiconductor component of claim 68, wherein the second zone, proceeding from the first zone, has a substantially constant dopant depth profile in the direction towards the field-free contact zone or field stop zone.

75. The electronic semiconductor component of claim 68, wherein the second zone, proceeding from the first zone, in the direction towards the field-free contact zone or field stop zone, has a dopant depth profile that rises in steps, wherein the steps are formed in a region of the second zone facing the field-free contact zone or field stop zone by up to 40% of the total depth of the second zone.

76. The electronic semiconductor component of claim 75, wherein a difference in concentration between the highest and lowest steps is at least a factor of 10.

77. The electronic semiconductor component of claim 68, wherein the second zone, proceeding from the first zone, has a constantly rising dopant depth profile in the direction towards the field-free contact zone or field stop zone.

78. The electronic semiconductor component of claim 77, wherein the continuously rising dopant depth profile is a profile according to the following formula:
$$D ( z ) = {D}_{max} \cdot ( \frac{1}{\sqrt{1 + ∝ ( 1 - \frac{z}{b} )}} \cdot f ) + {D}_{0}$$

79. The electronic semiconductor component of claim 68, further comprising a carrier substrate on a side of the field-free contact zone or field stop zone remote from the first zone, wherein the crystal made of SiC is bonded to the carrier substrate by means of a permanent adhesive bond or other bonded connection in the region of the field-free contact zone or field stop zone.

80. The electronic semiconductor component of claim 68, further comprising an inactive edge region that substantially completely surrounds the first zone and the second zone laterally in all directions.

81. The electronic semiconductor component of claim 80, wherein the edge region, apart from any near-surface field-reducing edge structure present, is substantially undoped.

82. The electronic semiconductor component of claim 80, wherein the edge region, apart from any near-surface field-reducing edge structure present, is substantially undoped from the first surface onward and, substantially from a depth at which the second zone commences up to a depth at which the field-free contact zone or field stop zone lies, has the same dopant concentration as the second zone or has a lower dopant concentration by at least 20% than the second zone.

83. The electronic semiconductor component of claim 68, wherein the field-free contact zone or field stop zone has a vertical thickness of not more than 2 μm.

84. The electronic semiconductor component of claim 67 or 68, wherein the monocrystalline SiC is of the hexagonal 4H or 6H polytype.

85. The electronic semiconductor component of claim 67 or 68, wherein the crystal is a crystal made of high-quality semi-insulating SiC material of high purity.

86. The electronic semiconductor component of claim 67 or 68, wherein the A plane of the crystal deviates by less than 0.5° from a direction perpendicularly to the first surface of the crystal.

87. The electronic semiconductor component of claim 67 or 68, wherein the electronic semiconductor component is a trench MOSFET, and the channel region deviates by less than 0.5° from the c direction of the crystal structure of the crystal.

88. The electronic semiconductor component of claim 67 or 68, wherein the electronic semiconductor component is a trench MOSFET, and the channel region deviates by less than 0.5° from a direction perpendicularly to the first surface of the crystal.

89. The electronic semiconductor component of claim 88, wherein the channel region is arranged in an A plane of the crystal.

90. The electronic semiconductor component of claim 67 or 68, wherein the electronic semiconductor component is a planar MOSFET, and the channel region deviates by less than 0.5° from a direction perpendicularly to the c direction of the crystal structure of the crystal.

91. The electronic semiconductor component of claim 67 or 68, wherein the electronic semiconductor component is a planar MOSFET, and the channel region runs parallel to the first surface of the crystal.

92. The electronic semiconductor component of claim 67 or 68, wherein the electronic semiconductor component is an MPS diode, and a plane of the Schottky junction deviates by less than 0.5° from a direction perpendicularly to the c direction of the crystal structure of the crystal.

93. The electronic semiconductor component of claim 67 or 68, wherein the electronic semiconductor component is an MPS diode, and a plane of the Schottky junction runs parallel to the first surface of the crystal.

94. The electronic semiconductor component of claim 67 or 68, wherein the electronic semiconductor component is a JFET transistor, wherein an interface at one or each p⁺-n junction deviates by less than 0.5° from a direction parallel to the c direction of the crystal structure of the crystal.

95. The electronic semiconductor component of claim 67 or 68, wherein the electronic semiconductor component is a JFET transistor, wherein an interface at one or each p⁺-n junction deviates by less than 0.5° from a direction perpendicularly to the c direction of the crystal structure of the crystal.
